(19) United States
(12) Patent Application Publication
(10) Pub. No.: US 2013/0313516 A1
(43) Pub. Date: Nov. 28, 2013

(54) LED LAMPS WITH IMPROVED QUALITY OF LIGHT

(71) Applicant: SORAA, INC., Fremont, CA (US)

(72) Inventors: Aurelien J. F. David, Fremont, CA (US); Troy A. Trottier, Fremont, CA (US); Michael R. Krames, Fremont, CA (US); Arpan Chakraborty, Fremont, CA (US); James W. Raring, Fremont, CA (US); Michael J. Grundmann, Fremont, CA (US)

(73) Assignee: SORAA, INC., Fremont, CA (US)

(21) Appl. No.: 13/886,547

(22) Filed: May 3, 2013

Related U.S. Application Data
(60) Provisional application No. 61/642,984, filed on May 4, 2012.
(60) Provisional application No. 61/783,888, filed on Mar. 14, 2013.

(51) Int. Cl. H01L 33/50; H01L 33/04; H01L 33/08

(52) U.S. Cl. CPC H01L 33/50; H01L 33/08; H01L 33/04
USPC 257/13; 257/89; 257/88

(57) ABSTRACT

LED lamps having improved light quality are disclosed. The lamps emit more than 500 lm and more than 2% of the power in the spectral power distribution is emitted within a wavelength range from about 390 nm to about 430 nm.

This application claims the benefit under 35 U.S.C. §119(e) of U.S. Provisional Application No. 61/642,984, filed on May 4, 2012, and U.S. Provisional Application No. 61/783,888, filed on Mar. 14, 2013, each of which is incorporated by reference in its entirety.

### FIELD

The disclosure relates to the field of general lighting with light emitting diode (LED) lamps and more particularly to techniques for LED lamps with improved quality of light.

### BACKGROUND

Due to the limited efficacy of common light sources, there is a need for high-efficiency LED sources for general lighting. In the recent past, technical progress has enabled LED-based lamps to provide enough luminous flux to replace general illumination sources in the 40 W range and beyond—for example, lamps emitting 500 lm and beyond. There is a strong push to keep increasing the lumen output of LED-based lamps while also improving the quality of the light they generate.

Therefore, there is a need for improved approaches.

### SUMMARY

Accordingly, techniques for LED lamps with improved quality of light are disclosed whereby the following configurations, systems and methods can be embodied.

In a first aspect, LED lamps are provided comprising an LED device, wherein the LED lamp is characterized by a luminous flux of more than 500 lm, and a spectral power distribution (SPD) in which more than 2% of the power is emitted within a wavelength range from about 390 nm to about 430 nm.

In a second aspect, LED-based lamps are provided characterized by a luminous flux of more than 500 lm, wherein the lamp comprises one or more LED source die having a base area of less than 40 mm².

In a third aspect, light sources are provided comprising a plurality of light emitting diodes (LEDs), for which at least 2% of an SPD is in a range 390 nm to 430 nm, and such that a CIE Whiteness of a high-whiteness reference sample illuminated by the light source is within minus 20 points to plus 40 points of a CIE Whiteness of the same sample under illumination by a CIE reference illuminant of same CCT (respectively a blackbody radiator if CCT<5000K or a D illuminant if CCT>5000K).

In a fourth aspect, light sources are provided comprising LEDs, for which at least 2% of an SPD is in a range about 390 nm to about 430 nm, and such that a CIE Whiteness of a high-whiteness reference sample illuminated by the light source is within minus 20 points to plus 40 points of a CIE Whiteness of the same sample under illumination by a ceramic metal halide illuminant of same CCT.

In a fifth aspect, light sources are provided comprising a plurality of light emitting diodes (LEDs), wherein light emitted by the light source is characterized by a spectral power distribution in which at least 2% of the power is in a wavelength range from about 390 nm to about 430 nm, and a chromaticity in which a high-whiteness reference sample illuminated by the source is at least two Duv points and at most twelve Duv points away from a chromaticity of a white point of the light source, and the chromaticity shift is substantially toward the blue direction of the colorspace.

In a sixth aspect, optical devices are disclosed comprising a bulk gallium and nitrogen containing substrate having a surface region; a n-type gallium and nitrogen containing epitaxial material formed overlying the surface region; an active region comprising a double heterostructure well region, and at least one dummy well configured on each side of the double heterostructure well region, each of the at least one dummy wells having a width of about ten percent to about ninety percent of a width of the double heterostructure well region; a p-type gallium and nitrogen containing epitaxial material formed overlying the active region; and a contact region formed overlying the p-type gallium and nitrogen containing epitaxial material.

### BRIEF DESCRIPTION OF THE DRAWINGS

Those skilled in the art will understand that the drawings, described herein, are for illustration purposes only. The drawings are not intended to limit the scope of the present disclosure.

FIG. 1A is a graph showing a comparison of the spectral power distribution (SPD) of a blackbody and a conventional LED lamp, using blue pump LEDs and one phosphor, with the same CCT of 3000K and an equal luminous flux for comparing to LED lamps with improved quality of light, according to some embodiments.

FIG. 1B is a graph showing a comparison of the SPD of a blackbody and a conventional LED lamp, using blue pump LEDs and one phosphor, with the same CCT of 6500K and an equal luminous flux for comparing to LED lamps with improved quality of light, according to some embodiments.

FIG. 2A is a picture of two reddish objects evidencing metamerism under illumination by a conventional LED source having a 2700K CCT, for comparison with LED lamps for improved quality of light.

FIG. 2B is a sketch of FIG. 2A that shows two reddish objects evidencing metamerism under illumination by a conventional LED source having a 2700K CCT for comparison with LED lamps with improved quality of light.

FIG. 3 is a graph showing the details of the short-wavelength SPD discrepancy (SWSD) between a conventional LED and a blackbody with the same CCT of 3000K and the same luminous flux for comparing LED lamps with improved quality of light, according to some embodiments.

FIG. 4 is a graph showing the total radiance factor of white paper with optical brightening agents for an incandescent source and a conventional LED source, both with a 3000K CCT, for comparing LED lamps with improved quality of light, according to some embodiments.

FIG. 5A depicts a reflector cup used in a system for LED lamps for comparing to LED lamps with improved quality of light, according to some embodiments.

FIG. 5B depicts a reflector cup having multiple LED sources for comparing to LED lamps with improved quality of light, according to some embodiments.

FIG. 6 depicts an experimental setup to measure cast shadows for comparing LED lamps with improved quality of light, according to some embodiments.

FIG. 7 depicts a graph showing relative luminous flux across a projected shadow versus angle, for a conventional LED-based MR-16 lamp for comparing to LED lamps with improved quality of light, according to some embodiments.

FIG. 8 is a sketch of an MR16 lamp body, an optical lens, and an LED source that includes violet pump LEDs and a phosphor mix used in LED lamps with improved quality of light, according to some embodiments.

FIG. 9A is a chart showing a comparison of modeled SPDs of a blackbody and an LED lamp with improved quality of light, both with a CCT of 3000K and with equal luminous flux, according to some embodiments.

FIG. 9B is a chart showing a comparison of SPDs of illuminants with a CCT of 300K for comparing against lamps with improved quality of light, according to some embodiments.

FIG. 10 is a chart showing a comparison of SPDs of a D65 illuminant versus LED lamps with improved quality of light, according to some embodiments.

FIG. 11 is a chart showing the short-wavelength SPD discrepancy between a blackbody radiator and certain embodiments, both with a CCT of 3000K, as a function of the SPD violet fraction for comparing LED lamps with improved quality of light, according to some embodiments.

FIG. 12 is a chart showing the short-wavelength SPD discrepancy between a D65 illuminant and embodiments, both with a CCT of 6500K, as a function of the SPD violet fraction for comparing LED lamps with improved quality of light, according to some embodiments.

FIG. 13A is a picture showing two reddish objects under illumination by a conventional LED source and by a particular configuration, both with a 2700K CCT.

FIG. 13B is a sketch of FIG. 13A showing two reddish objects under illumination by a conventional LED source, and by a configuration of the invention, both with a 2700K CCT.

FIG. 14 is a chart showing the total radiance factor of a sample of white paper with optical brightening agents, for an incandescent source and a selected embodiment, both with a 3000K CCT for comparing LED lamps with improved quality of light, according to some embodiments.

FIG. 15 is a chart showing the CIE whiteness of calculated sources with a 6500K CCT for comparisons of LED lamps with improved quality of light, according to some embodiments.

FIG. 16A is a chart showing the CIE whiteness of calculated sources with a 3000K CCT for comparisons of LED lamps with improved quality of light, according to some embodiments.

FIG. 16B is a chart showing the CCT-corrected Whiteness of sources with a 3000K CCT for comparisons of LED lamps with improved quality of light, according to some embodiments.

FIG. 17 is a chart showing the relative luminous flux across a projected shadow versus angle for a conventional LED-based MR-16 lamp and an embodiment for comparisons of LED lamps with improved quality of light, according to some embodiments.

FIG. 18A is a picture showing shadows cast by a hand under illumination by a conventional LED lamp with multiple light sources.

FIG. 18B is a picture showing a shadow cast by a hand under illumination by an embodiment as disclosed herein.

FIG. 19A depicts an MR-16 form factor lamp used in LED lamps with improved quality of light, according to some embodiments.

FIG. 19B depicts a PAR30 form factor lamp used in LED lamps with improved quality of light, according to some embodiments.

FIG. 19C1 and FIG. 19C2 depicts an AR111 form factor lamp for use with LED lamps with improved quality of light, according to some embodiments.

FIG. 19D1 and FIG. 19D2 depicts a PAR38 form factor lamp for use with LED lamps with improved quality of light, according to some embodiments.

FIG. 20 is a chart that indicates the center beam candle power requirements for 50-watt MR-16 lamps as a function of the beam angle.

FIG. 21 is a chart showing the experimentally-measured CCT-corrected Whiteness of various objects illuminated by various illuminants for comparisons of LED lamps with improved quality of light, according to some embodiments.

FIG. 22 is a chart 2200 showing the (x,y) coordinates of a high whiteness reference standard illuminated by various sources with a 3000K CCT for comparisons of LED lamps with improved quality of light, according to some embodiments.

FIG. 23 is a chart showing the experimental SPD of an LED lamp having a CCT of 5000K, according to some embodiments.

FIG. 24 is a simplified diagram of packaged light emitting devices using a flat carrier and cut carrier;

FIG. 25 to FIG. 36 are diagrams of alternative packaged light emitting devices using reflection mode configurations;

FIG. 37 shows schematic diagrams of the band gap structures for a single quantum well (SQW), multiple quantum well (MQW), and double heterostructure (DH) known in the prior art; and for SDH-land SDH-2 as provided by the present disclosure.

FIGS. 38A-38D show the EL100 power (mw) vs. wavelength (nm) for standard LED structures and m-plane SDH LED structures provided by the present disclosure (FIG. 38A); EL1000 power (mw) vs. wavelength (nm) for standard structures and m-plane SDH LED structures provided by the present disclosure (FIG. 38B); the external quantum efficiency (%) vs. current density (A/cm²) for packaged LEDs (FIG. 38C); and the roll-off in the percent external quantum efficiency for current densities form 100 A/cm² to 400 A/cm² for a standard LED and SDH LEDs provided by the present disclosure (FIG. 38D).

FIG. 39A shows the Z-factor (hot/cold factor, %) vs. EL100 wavelength (nm) at 130° C. for non-SDH LEDs and SDH LEDs provided by the present disclosure. The measurements were made on m-plane SDH structures. For devices with AlGan barriers and cladding layers, a Z-factor in excess of 80% was measured on-wafer.

FIG. 39B shows the Z-factor (hot/cold factor, %) vs. EL1000 wavelength (nm) at 130° C. for non-SDH LEDs and SDH LEDs provided by the present disclosure.

FIG. 40 shows the low temperature photoluminescence performance of m-plane SDH LEDs. The chart shows the internal quantum efficiency vs. J for m-plane SDH LEDs provided by the present disclosure at temperatures of 4K, 75K, 300K, and 423K.

FIG. 41 shows a chart of the external quantum efficiency vs. current density (A/cm²) for m-plane SDH LEDs provided by the present disclosure. As shown, an EQE of about 45% at 400 A/cm² was obtained for a device with non-optimized light extraction. The current droop of less than 5% form the peak to 400 A/cm² was observed. A hot/cold factor greater than 78% at 150° C. equivalent to a thermal droop less than 22% between room temperature and 150° C. was also observed.

FIG. 42 outlines an embodiment of a LED device structure according to certain embodiments.

### DETAILED DESCRIPTION

The term “phosphors” as used herein means any compositions of wavelength-converting materials.

The term “CCT” refers to the correlated color temperature.

The term “SPD” as used herein means the spectral power distribution of a spectrum (e.g., its distribution of spectral power versus wavelength).

The term “FWHM” as used herein means full-width at half maximum of an SPD.

The term “OBA” as used herein refers to an optical brightening agent, substance which absorbs light in a wavelength range and emits light in another wavelength range to increase perceived whiteness. Typically conversion occurs from the ultraviolet-violet range to the blue range.

The acronym “SWSD” as used herein refers to a short-wavelength SPD discrepancy, a metric to quantify the discrepancy between two SPDs in the short-wavelength range. This metric is defined further in the application.

The term “total radiance factor” as used herein refers to the ratio of the radiation reflected and emitted from a body to that reflected from a perfect reflecting diffuser under the same conditions of illumination and detection.

The term “Duv” as used herein refers to the chromaticity difference between two color points of color coordinates (u′1,v′1) and (u′2,v′2), and is defined as:

Duv=1000·\sqrt{(u′1−u′2)²+(v′1−v′2)²}

The term “violet leak” as used herein refers to the fraction of an SPD in the range 390 nm to 430 nm.

The term “CCT-corrected Whiteness” as used herein refers to a generalization of the CIE whiteness formula applicable to CCTs other than 6500K.

The term “high whiteness reference sample” as used herein refers to a commercially available whiteness standard whose nominal CIE whiteness is about 140, as further described herein.

The term “Large-sample set CRI” as used herein refers to a generalization of the color rendering index where the color-error calculation is averaged over a large number of samples rather than eight samples, as further described herein.

Reference is now made in detail to certain embodiments. The disclosed embodiments are not intended to be limiting of the claims.

Wavelength conversion materials can be ceramic or semiconductor particle phosphors, ceramic or semiconductor plate phosphors, organic or inorganic downconverters, upconverters (anti-stokes), nanoparticles and other materials which provide wavelength conversion. Some examples are listed below:
(Srₙ,Ca₁₋ₙ)₁₀(PO₄)₆*B₂O₃:Eu²⁺ (wherein 0≦n≦1)
(Ba,Sr,Ca)₅(PO₄)₃(Cl,F,Br,OH):Eu²⁺,Mn²⁺
(Ba,Sr,Ca)BPO₅:Eu²⁺,Mn²⁺
Sr₂Si₃O₈*2SrCl₂:Eu²⁺
(Ca,Sr,Ba)₃MgSi₂O₈:Eu²⁺, Mn²⁺
BaAl₈O₁₃:Eu²⁺
2SrO*0.84P₂O₅*0.16B₂O₃:Eu²⁺
(Ba,Sr,Ca)MgAl₁₀O₁₇:Eu²⁺,Mn²⁺
K₂SiF₆:Mn⁴⁺
(Ba,Sr,Ca)Al₂O₄:Eu²⁺
(Y,Gd,Lu,Sc,La)BO₃:Ce³⁺,Tb³⁺
(Ba,Sr,Ca)₂(Mg,Zn)Si₂O₇:Eu²⁺
(Mg,Ca,Sr,Ba,Zn)₂Si₁₋ₓO₄₋₂ₓ:Eu²⁺ (wherein 0≦x≦0.2)
(Ca,Sr,Ba)MgSi₂O₆:Eu²⁺
(Sr,Ca,Ba)(Al,Ga)₂S₄:Eu²⁺
(Ca,Sr)₈(Mg,Zn)(SiO₄)₄Cl₂:Eu²⁺,Mn²⁺
Na₂Gd₂B₂O₇:Ce³⁺,Tb³⁺
(Sr,Ca,Ba,Mg,Zn)₂P₂O₇:Eu²⁺,Mn²⁺
(Gd,Y,Lu,La)₂O₃:Eu³⁺,Bi³⁺
(Gd,Y,Lu,La)₂O₂S:Eu³⁺,Bi³⁺
(Gd,Y,Lu,La)VO₄:Eu³⁺,Bi³⁺
(Ca,Sr)S:Eu²⁺,Ce³⁺
(Y,Gd,Tb,La,Sm,Pr,Lu)₃(Sc,Al,Ga)₅₋ₙO_{12-3/2n}:Ce³⁺ (wherein 0≦n≦0.5)
ZnS:Cu+,Cl−
(Y,Lu,Th)₃Al₅O₁₂:Ce³⁺
ZnS:Cu⁺,Al³⁺
ZnS:Ag⁺,Al³⁺
ZnS:Ag⁺,Cl⁻
LaAl(Si_{6-z}Al_{z})(N_{10-z}O_{z}):Ce³⁺ (wherein z=1)
(Ca,Sr)Ga₂S₄:Eu²⁺
AlN:Eu²⁺
SrY₂S₄:Eu²⁺
CaLa₂S₄:Ce³⁺
(Ba,Sr,Ca)MgP₂O₇:Eu²⁺,Mn²⁺
(Y,Lu)₂WO₆:Eu³⁺,Mo⁶⁺
CaWO₄
(Y,Gd,La)₂O₂S:Eu³⁺
(Y,Gd,La)₂O₃:Eu³⁺
(Ba,Sr,Ca)ₙSiₙNₙ:Eu²⁺ (where 2n+4=3n)
Ca₃(SiO₄)Cl₂:Eu²⁺
(Y,Lu,Gd)₂₋ₙCaₙSi₄N₆₊ₙ,C₁₋ₙ:Ce³⁺, (wherein 0≦n≦0.5)
(Lu,Ca,Li,Mg,Y) alpha-SiAlON doped with Eu²⁺ and/or Ce³⁺
(Ca,Sr,Ba)SiO₂N₂:Eu²⁺,Ce³⁺
Ba₃MgSi₂O₈:Eu²⁺,Mn²⁺
(Sr,Ca)AlSiN₃:Eu²⁺
CaAlSi(ON)₃:Eu²⁺
Ba₃MgSi₂O₈:Eu²⁺
LaSi₃N₅:Ce³⁺
Sr₁₀(PO₄)₆Cl₂:Eu²⁺
(BaSi)O₁₂N₂:Eu²⁺
M(II)ₐSi_{b}O_{c}N_{d}Ce:A wherein(6<a<8, 8<b<14, 13<c<17, 5<d<9, 0<e<2) and M(II) is a divalentcation of (Be,Mg,Ca,Sr,Ba,Cu,Co,Ni,Pd,Tm,Cd) and A of (Ce,Pr,Nd,Sm,Eu,Gd,Tb,Dy,Ho,Er,Tm,Yb,Lu,Mn,Bi,Sb)
SrSi₂(O,Cl)₂N₂:Eu²⁺
SrSi₉Al₁₉ON₃₁:Eu²⁺
(Ba,Sr)Si₂(O,Cl)₂N₂:Eu²⁺
LiM₂O₈:Eu³⁺ where M=(W or Mo)

For purposes of the application, it is understood that when a phosphor has two or more dopant ions (i.e., those ions following the colon in the above phosphors), this is to mean that the phosphor has at least one (but not necessarily all) of those dopant ions within the material. That is, as understood by those skilled in the art, this type of notation means that the phosphor can include any or all of those specified ions as dopants in the formulation.

Further, it is to be understood that nanoparticles, quantum dots, semiconductor particles, and other types of materials can be used as wavelength-converting materials. The list above is representative and should not be taken to include all the materials that may be utilized within the embodiments described herein. Due to the limited efficacy of common light sources, there is a need for high-efficiency LED sources for general lighting. In the recent past, technical progress has enabled LED-based lamps to provide enough luminous flux to replace general illumination sources in the 40W range and beyond, e.g., lamps emitting 500 lm and beyond.

Such conventional LED lamps use pump LEDs emitting in the range 440 nm to 460 nm and a mix of phosphor to generate white light. The choice of blue pump LEDs (e.g., around 450 nm) for use in conventional LED lamps has in part been driven by the level of performance of such LEDs, which has made it possible to produce enough light (e.g., 500 lm) to suffice for some general lighting applications.

There is a strong push to keep increasing the lumen output of LED-based lamps, and also to improve the quality of the light they generate.

LED-based lamps are composed of several elements, including:
An LED source (or module) including LEDs and phosphors, which generate light;
A lamp body to which the LED source is attached; and
An optical lens or other optical element that redirects or diffuses the light emitted by the LED source.

Below, are discussed some important limitations to the quality of light emitted by conventional LED lamps. Some of these issues are related to the use of blue pump LEDs, and some are related to the use of an extended LED light source and/or multiple LED light sources.

The color rendering index (CRI) is a recognized metric frequently employed to assess the quality of a light source. It provides a metric pertaining to the ability of a light source to reproduce the color rendering of a reference illuminant with the same correlated color temperature (CCT). However, under a variety of scenarios, the aforementioned CRI fails at correctly describing color rendering.

Indeed, the CRI only approximately evaluates the similarity between an ideal blackbody radiator and a light source in that the colors of illuminated test color samples (TCS) are compared. These TCSs display broad reflection spectra with slow variations, therefore, sharp variations in the spectral power distribution (SPD) of the source are not penalized. The TCS tests do not pose a very stringent test in terms of color matching: they are forgiving of spectral discrepancies which occur in a narrow range of wavelengths.

However, there exist situations where the human eye is sensitive to minute changes in SPD, for instance when looking at objects with less regular reflection spectra, or objects whose reflection spectra are not close to one of the CRI TCSs. In such cases, a discrepancy between the SPD of the blackbody and the source over a narrow wavelength range may be perceived by an observer, and judged as an inadequate color rendering. Thus the only way to really avoid illuminant metamerism is to match the SPD of a reference illuminant at all wavelengths.

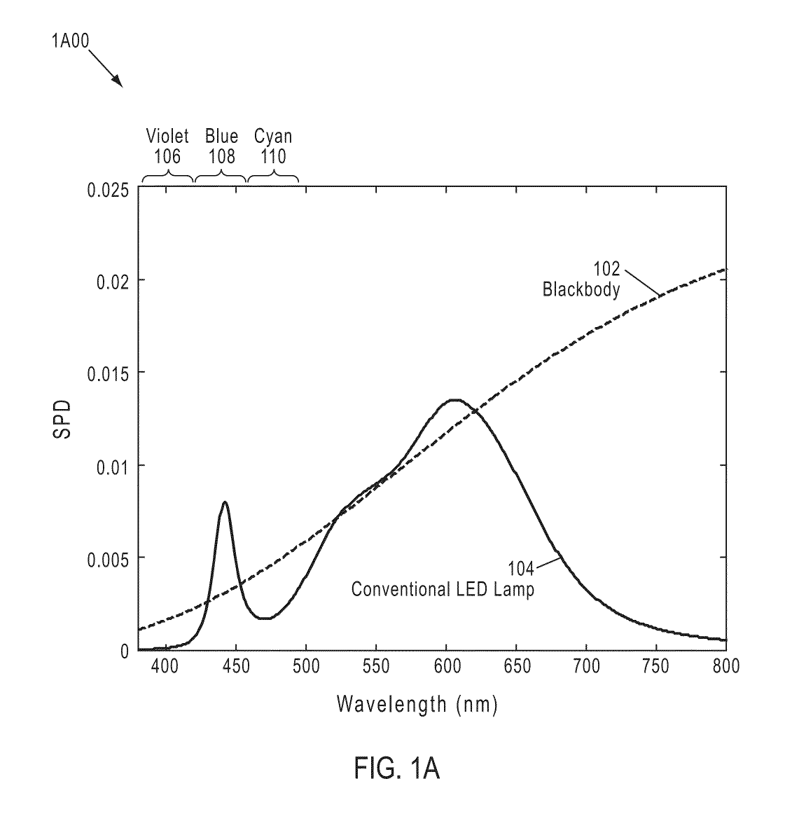

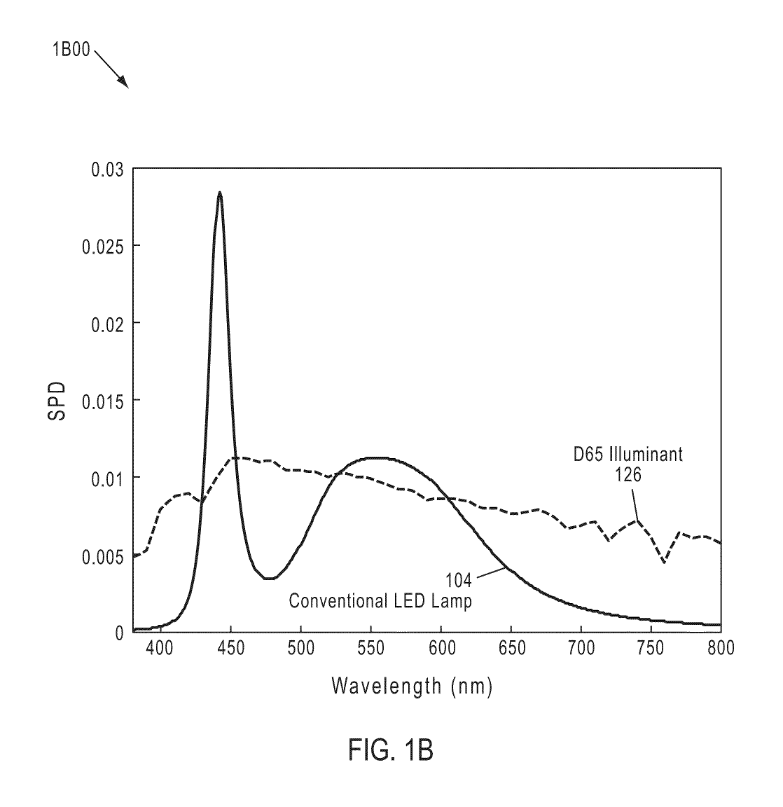

FIG. 1A is a graph 1A00 showing a comparison of the SPDs of a blackbody 102 and a conventional LED lamp 104, using blue pump LEDs and one phosphor, with the same CCT of 3000K and having equal luminous flux for comparing to LED lamps with improved quality of light.

The compared SPDs of reference illuminants and conventional LEDs are shown in FIG. 1A and FIG. 1B, respectively for CCTs of 3000K and 6500K (for 3000K the reference is a blackbody 102, and for 6500K it is the D65 illuminant 126). The SPD discrepancy is especially notable in the short-wavelength range in that conventional LED sources employ blue pump LEDs with a narrow spectrum centered around 450 nm, and phosphor emission at longer wavelengths, separated by the Stokes shift between phosphor excitation and emission. Therefore, their SPD is too intense in the blue range 108 around 450 nm, too weak in the violet range 106, (390 nm to 430 nm), and weak in the cyan range 110 (470 nm to 500 nm) due to the Stokes shift.

FIG. 1B is a graph 1B00 showing a comparison of SPD of a reference illuminant (D65 illuminant 126) and a conventional LED lamp 104, using blue pump LEDs and one phosphor, with the same CCT of 6500K and an equal luminous flux, for comparing to LED lamps with improved quality of light.

As earlier described, at various CCTs, including the shown SPDs at 6500K, discrepancy is especially notable in the short-wavelength range in that conventional LED sources employ blue pump LEDs with a narrow spectrum centered around 450 nm, and phosphor emission at longer wavelengths, separated by the Stokes shift between phosphor excitation and emission.

Moreover, such discrepancies are not well described by the CRI. Indeed, recent academic research indicates that the color-matching functions underlying the CRI underestimate the sensitivity of the human eye in the short-wavelength range (e.g., for violet, blue and cyan wavelengths). Therefore, the importance of matching a reference spectrum at short wavelength is not properly described by the CRI, and little emphasis has been put on this issue in conventional LED sources. Improving SPD matching in this range can improve actual quality of light beyond what the CRI predicts.

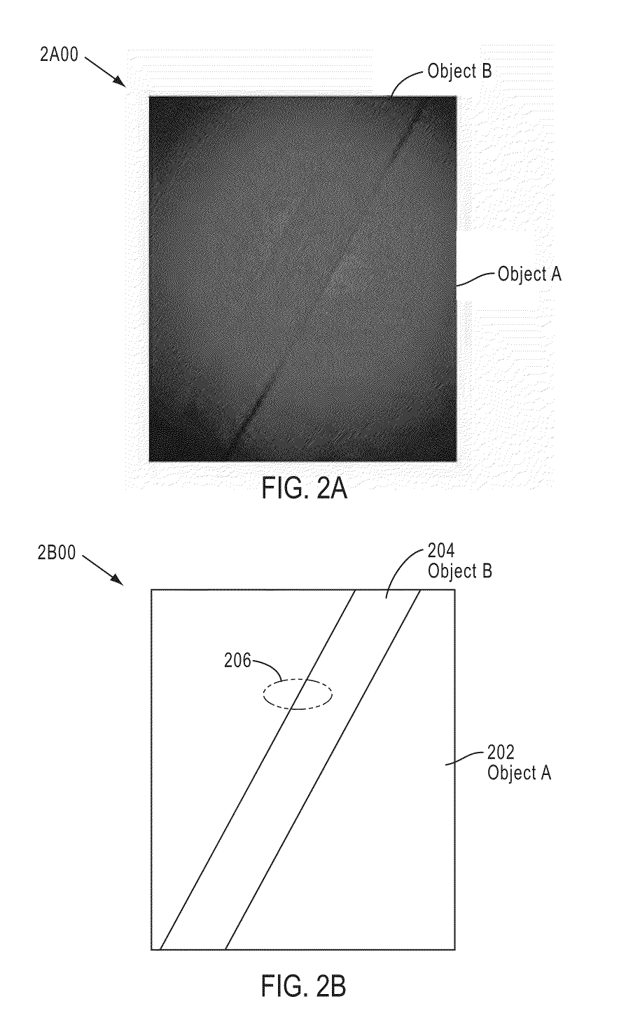

FIG. 2A is a picture 2A00 showing two reddish objects under illumination by a conventional LED source with a 2700K CCT, for comparison with LED lamps with improved quality of light.

FIG. 2A shows two reddish fabrics which have the same color point under daylight illumination. The picture is taken under illumination by a 2700K conventional LED source. The color of the objects appear markedly different, with object A (202) being more orange and object B (204) being more blue. This is a manifestation of metamerism (e.g., the effect that two objects similar under a particular illuminant can appear different under another illuminant). In some cases this is not desirable. Here, as shown, the two fabrics are designed to match in color, however under LED illumination they appear different (e.g., due to human visual perception).

FIG. 2B is a sketch 2B00 of FIG. 2A which shows two reddish objects under illumination by a conventional LED source with a 2700K CCT for comparison with LED lamps with improved quality of light.

FIG. 2B shows two fabrics which have the same color point under daylight illumination. As depicted by the sketch, the color of the objects appear markedly different—this is a manifestation of metamerism. In some cases this is not desirable. Here the two fabrics (object A 202 and object B 204) are designed to match in color, but under certain LED illumination conditions, they appear different.

To quantify SPD matching more accurately than the CRI, one could use the CRI method (comparison of color coordinates for a set of standards), however an alternative is to use a wider variety of standards, including standards with sharper reflectivity spectra and a larger gamut than given in the TCS in order to better sample details of the SPD.

Embodiments described herein generalize the CRI correspondence to a larger variety of standards. A large number of physically-realistic, random reflectance spectra can be simulated numerically. Such a spectra collection covers the entire color space. By using such methods (e.g., one of the methods of Whitehead and Mossman), one can compute a large number of such spectra, for instance 10⁶ spectra, and use these spectra rather than the conventional TCS. The color error of each spectrum can be calculated. Further, since many spectra correspond to similar coordinates in colorspace (for instance in 1964 (uv) space), due to metamerism, the colorspace can be defined using discrete spectral cells, and the average color error in each cell of the colorspace can be computed. Also, the color error can be averaged over all cells to yield a Large-sampleset CRI value. As further discussed herein, this technique is well-behaved; for example, different sets of random spectra yield a similar Large-sampleset CRI value (e.g., within about one point) for realistic LED spectra, and the Large-sampleset CRI value does not depend significantly on the details of the discretization grid. By using this approach, a conventional LED lamp (having a CRI of about 84) has a Large-sampleset CRI of only about 66, which is a much lower value. This indicates that by widening the CRI approach to a large set of samples (e.g., covering the entire color space), the estimation of color rendering can be significantly improved. Quantitative analysis indicates that differences in estimation values are mainly due to the short- and long-wavelength ends of the LED source spectrum where departure from a blackbody SPD is pronounced.

Another straightforward way to estimate SPD discrepancy is to integrate the distance between the two SPDs over the visible wavelength range, weighted by proper response functions. For instance, one can choose the cone fundamentals S, L and M (the physiological response of the cone receptors in a human eye). The short-wavelength response S is especially sensitive in the range of about 400 nm to about 500 nm, and is a suitable weighting function to quantify SPD discrepancy in this range.

Exemplary quantifications define the short-wavelength SPD discrepancy (SWSD) as:

$$S W S D = \frac{\int \vert BB ( λ ) - LED ( λ ) \vert \cdot S ( λ ) \cdot d λ}{\int BB ( λ ) \cdot S ( λ ) \cdot d λ}$$

Here LED(λ) is the SPD of the LED source. BB(λ) is the SPD of a reference illuminant with the same CCT and equal luminous flux. As is customary, the reference illuminant is a blackbody below 5000K, and a phase of CIE standard illuminant D otherwise. S(λ) is the short-wavelength cone fundamental. Note that similar functions can be defined for the other cone response functions L and M, if one studies SPD discrepancies at longer wavelengths.

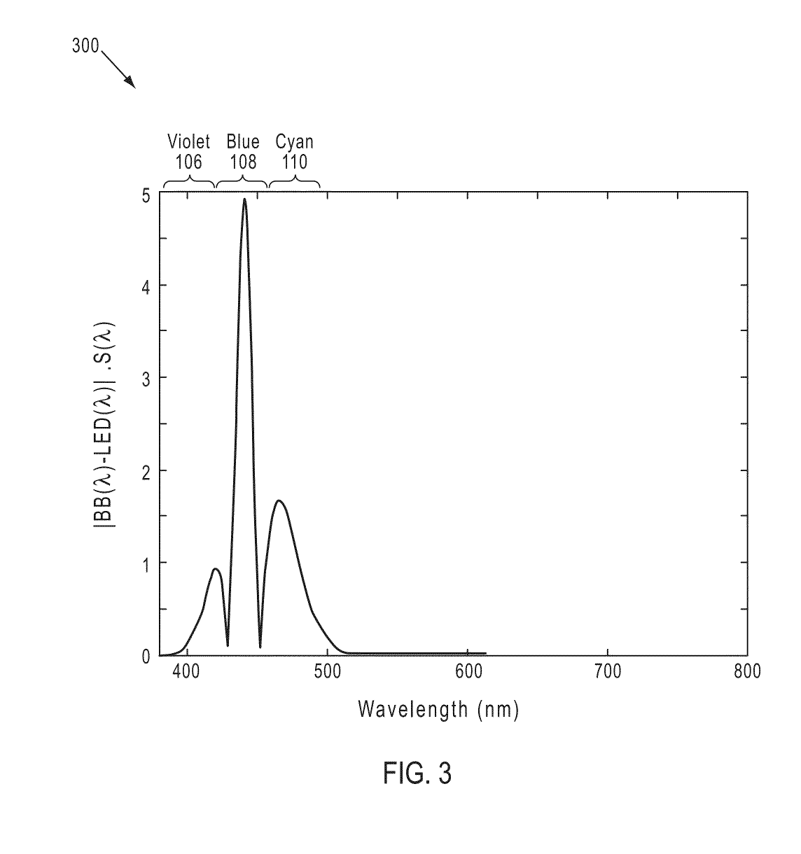

FIG. 3 is a graph 300 showing the details of the SWSD between a conventional LED and a blackbody with the same CCT of 3000K and the same luminous flux for comparing LED lamps with improved quality of light.

FIG. 3 depicts the details of the SWSD for a conventional commercial LED source with a 3000K CCT. As expected, contributions to the discrepancy arise from the violet range 106, the blue range 108 and cyan range 110.

Observers will recognize that in some applications, very vivid colors are desired. In some such applications, color fidelity is less important than color saturation. Thus one does not seek a perfect match to a blackbody SPD but rather a SPD which will exacerbate color saturation/chromaticity. Again, this effect is not captured by CRI values.

While it is important for a lamp to properly render colors, the rendering of white is especially crucial. These two criteria are not equivalent. Indeed, most white objects in everyday life display a high whiteness thanks to the use of fluorescent species, commonly referred to as optical brightening agents (OBAs) or fluorescent whitening agents (FWAs). These OBAs absorb light in the ultraviolet/violet wavelength range and fluoresce in the blue range. Additional spectral contribution in the blue range is known to increase human perception of whiteness. Objects commonly containing OBAs include white paper, white fabrics, and washing detergents.

As was shown in FIG. 1A and FIG. 1B, the SPD of a conventional LED source lacks any contribution in the violet and ultraviolet ranges. Therefore, OBA fluorescence is not excited and the perceived whiteness is decreased.

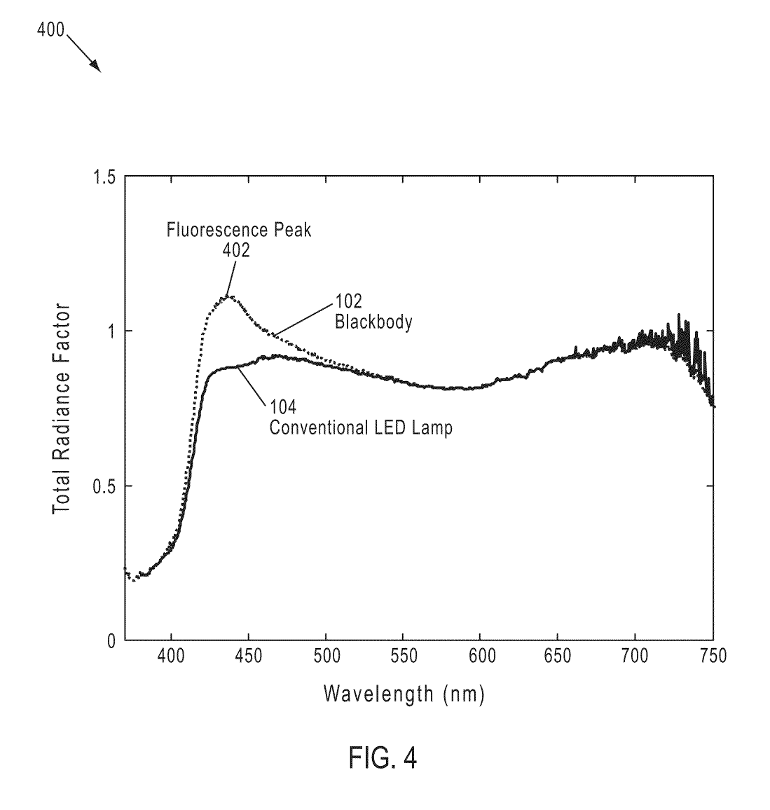

FIG. 4 is a graph 400 showing the total radiance factor of a sample of white paper with optical brightening agents for an incandescent source and a conventional LED source, both with a 3000K CCT, for comparing LED lamps with improved quality of light.

FIG. 4 illustrates this by comparing the total radiance factors of a sheet of white paper illuminated by a blackbody radiator (in practice, a halogen lamp) and a conventional LED, with the same CCT of 3000K. The total radiance factor represents the emitted light normalized by the source SPD, and is composed of a reflection and of fluorescence contributions. For the blackbody 102, a pronounced peak (e.g., fluorescence peak 402) is observed around 430 nm (the total radiance factor is higher than unity); this is due to fluorescence of OBAs excited by ultraviolet and violet light. For the conventional LED lamp 104, on the other hand, no fluorescence is excited and the total radiance factor is simply equal to the reflectivity spectrum of the paper sheet.

Various light sources are able to excite OBAs because their SPD contains violet and ultraviolet light. Such light sources include certain incandescent and halogen sources, and certain ceramic metal halide sources.

In order to quantify this effect one can use the CIE whiteness, a recognized metric for whiteness evaluation. CIE whiteness is defined in “Paper and board—Determination of CIE whiteness, D65/10° (outdoor daylight)”, ISO International Standard 11475:2004 E (2004).

Table 1 considers a commercially-available high-whiteness paper illuminated by various illuminants, and indicates the corresponding CIE whiteness. In characterizing the reference illuminants, the presented values assume no emissions below 360 nm (e.g., due to the presence of UV cutoff filters in the corresponding lamps). The whiteness under conventional blue-pumped LED illumination is significantly lower than under incandescent illumination. Note that, for a CCT of 3000K, whiteness values are always negative; this is due to the definition of CIE whiteness, which uses a reference illuminant at 6500K. Therefore, absolute values of CIE whiteness are not indicative for CCTs other than 6500K; however, relative changes in CIE whiteness are still indicative of a change in whiteness rendering because they quantify the desired color shift toward the blue which enhances the perception of whiteness. Therefore, the 30-point difference in CIE whiteness between the reference illuminant and the LED is suggestive of a large difference in perceivable whiteness.

TABLE 1

| | Reference | LED |
|---|---|---|
| 6500K | 125 | 90 |
| 3000K | −137 | −165 |

Instead of directly employing the equation for CIE whiteness, which is defined for a CCT of 6500K, one can also adapt the CIE whiteness formula to a source of a different CCT. This can be done through known-in-the-art mathematics considering the foundations of the CIE whiteness formula. Exemplary mathematical treatments include a derivation of a formula similar to that of CIE whiteness but with modified numerical coefficients, which is referred to herein using the term “CCT-corrected Whiteness”. CCT-corrected Whiteness quantifies the blue-shift of objects containing OBAs under illumination; however since the CCT of the illuminant is taken into account when using the CCT-corrected Whiteness formula, the resulting whiteness values are positive, and absolute values are meaningful for any CCT.

Table 2 shows the CCT-corrected Whiteness value for a 300K illuminant over the same commercially-available paper as in the above discussion referring to Table 1. As discussed, the absolute values of CCT-corrected Whiteness are meaningful as they reveal a large change in whiteness between the two illuminants.

TABLE 2
CCT-corrected Whiteness value for a 300K illuminant

| CCT | Reference | Reference |
|---|---|---|
| 3000K | 113 | 86 |

In summary, the discussion above shows that conventional LEDs are unable to render whiteness in objects containing OBAs due to the lack of violet or UV radiation in their SPD.

### Shadow Management

Lamps generate shadows. The appearance of the shadows depends on the properties of the lamp. In general an extended light source will generate damped, blurred shadows whereas a point-like light source will generate very sharp shadows. This is especially true when the illuminated object is located close to the lamp. It is easy to decrease shadow sharpness (for instance by adding a reflector cup or a diffuser to the light source). On the other hand, there is no easy way to obtain sharp shadows from an extended source. Sharp shadows are desirable in some applications.

In order to be useful for general lighting, LED lamps need to deliver a minimum luminous flux. Due to limitations in power dissipation and source efficiency, this is often achieved by placing several LED sources in a lamp fixture. These LED sources are distributed across the lamp, and therefore increase the source size and generate blurred shadows. This is also true for some incandescent sources such as halogen MR-16 lamps, which use a large reflector cup.

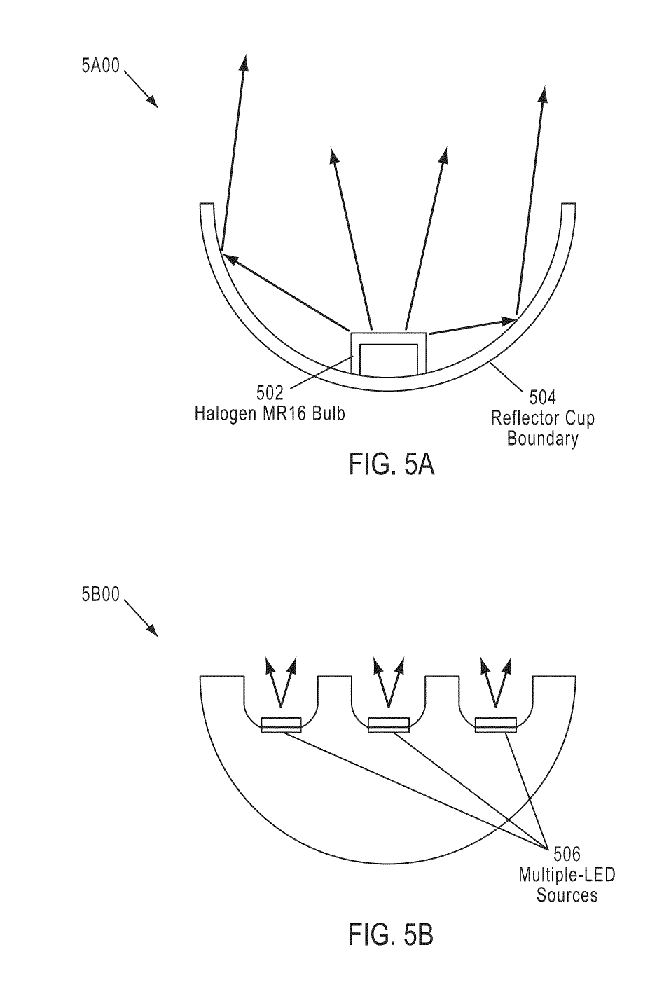

FIG. 5A depicts a reflector cup 5A00 used in a system for LED lamps with improved quality of light.

FIG. 5A and FIG. 5B depict a halogen MR-16 bulb 502 and a multiple-source LED MR-16 506 with an extended source area provided by a reflector cup boundary 504. Of course, lamps consisting of multiple light sources 506 (e.g., LEDs) produce multiple shadows which are considered undesirable since they tend to “pollute” an illuminated scene and can distract observers. It is not possible to achieve a single-shadow situation from a multi-source lamp unless the lamp is distant from the illuminated objects.

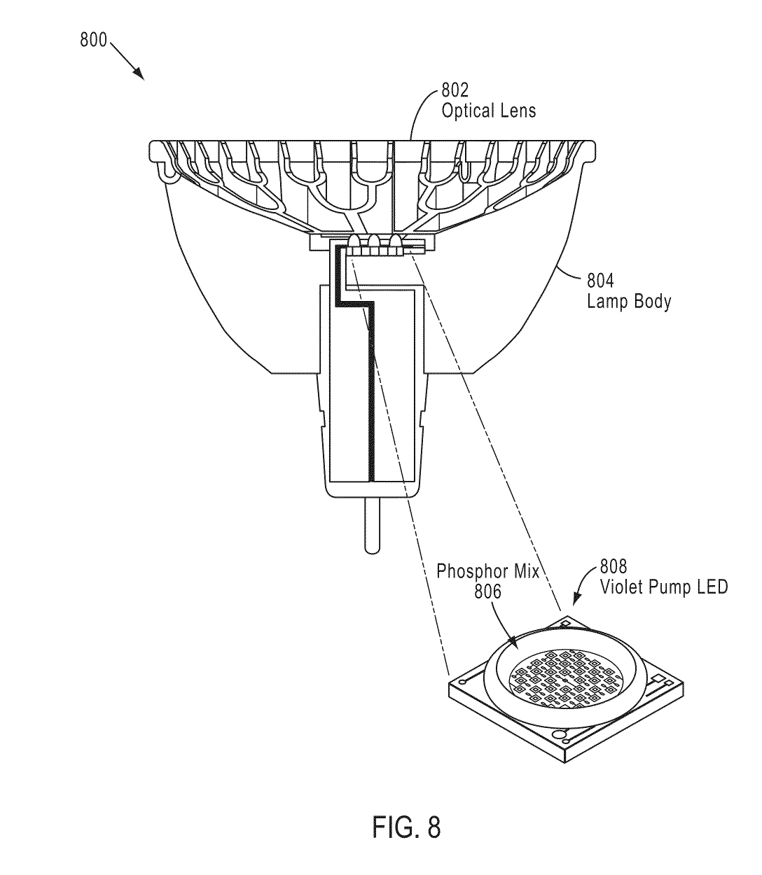

FIG. 5B depicts a reflector cup 5B00 having multiple LED sources for comparing to LED lamps with improved quality of light. What is needed to improve the quality of shadows is a single-source with limited lateral extension (e.g., see FIG. 8).

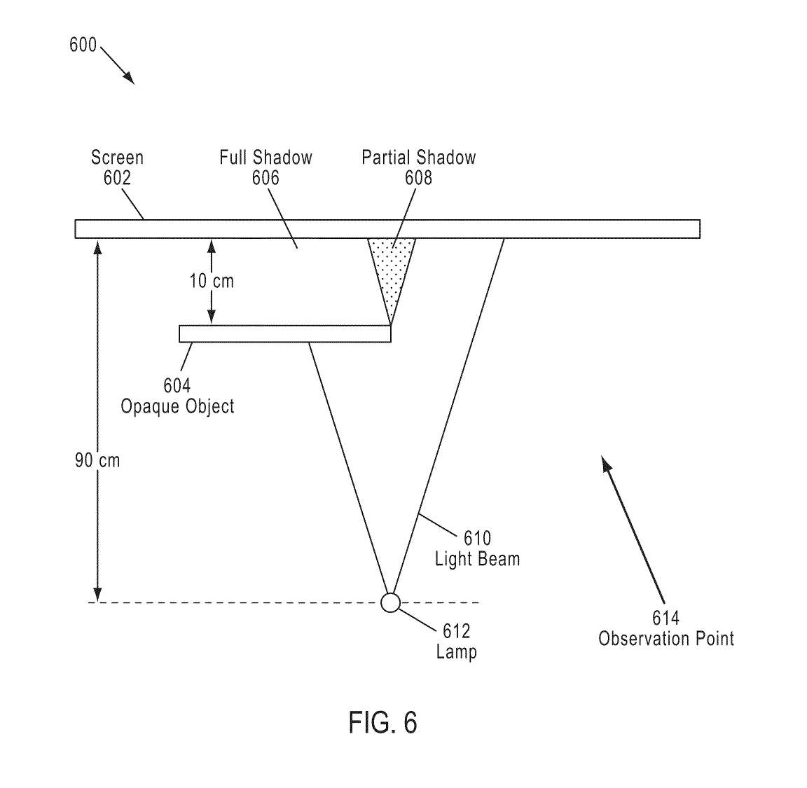

FIG. 6 depicts an experimental setup 600 to measure cast shadows for comparing LED lamps with improved quality of light.

FIG. 6 describes an experimental setup which can be used to evaluate the sharpness of a shadow. A lamp 612 is located 90 cm away from a screen 602, and the edge of an opaque object 604 is located at the center of the light beam 610, 10 cm away from the screen. The cast shadow is observed from observation point 614 at a distance of 1.2 m and an observation angle of 25 degrees. Also shown are a depiction of a full shadow 606 and a depiction of a partial shadow 608. The full shadow 606 corresponds to the area of the screen where no light impinges. The partial shadow 608 corresponds to the area of the screen where some light impinges, and across which light intensity transitions from full signal to no signal.

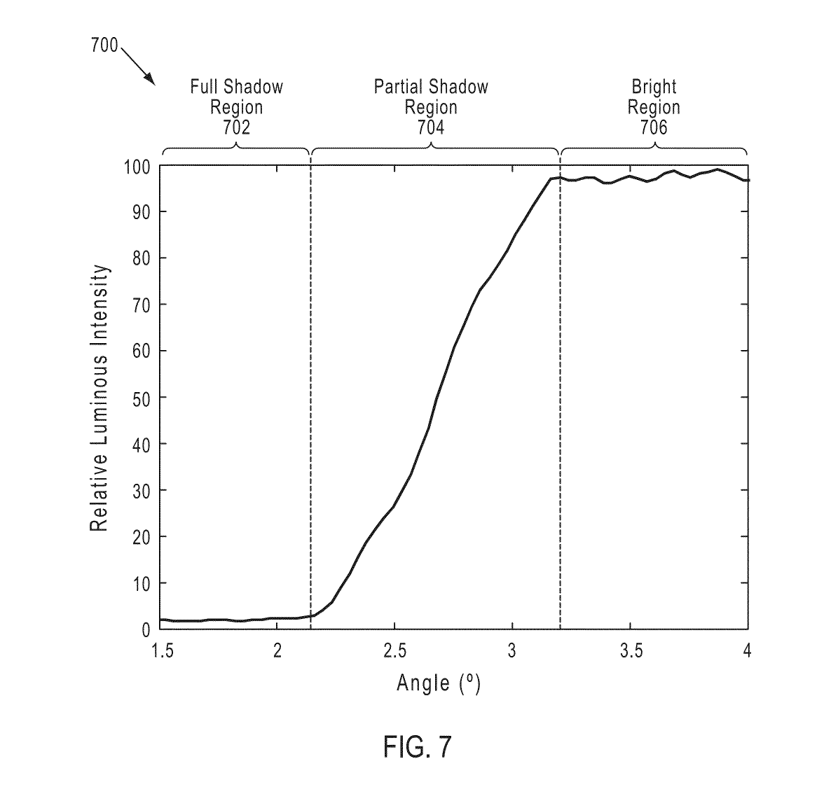

FIG. 7 depicts a graph 700 showing relative luminous flux across a projected shadow versus angle for a conventional LED-based MR-16 lamp for comparing to LED lamps with improved quality of light. The dashed vertical lines mark the beginning and end of the partial shadow region.

FIG. 7 shows a cross-section of the cast shadow in such an experiment. The luminous intensity shows a bright region 706, a full shadow region 702, and a partial shadow region 704. The sharpness of the shadow can be quantified by the angular width of the partial shadow region, 1 degree in this case. Here the source is a conventional LED MR-16 lamp, but a wide variety of LED-based and halogen MR-16 lamps show very similar results.

Finally, lamps with multiple LED sources sometimes employ LEDs of different color points; for instance, one of the sources may have a slightly bluer SPD and another slightly more red SPD, the average reaching a desired SPD. In this case, the generated shadow is not only blurred, but also displays color variation which is not desirable. This can be evaluated by measuring the (u′, v′) color coordinates in different parts of the partial shadow.

What is needed is an LED light source which can deliver sufficient flux for general illumination, and at the same time address some or all of the following issues: spectral matching to a reference SPD, high whiteness, and small LED source size.

The herein-disclosed configurations are LED-based lamps providing a sufficient flux for general illumination and with improved light quality over a standard LED-based lamp.

An exemplary embodiment is as follows: an MR-16 lamp including an optical lens with a diameter of 30 mm, and an LED-based source formed of violet-emitting LEDs pumping three phosphors (a blue, a green and a red phosphor) such that 2% to 10% of the emitted power is in the range 390 nm to 430 nm. The lamp emits a luminous flux of at least 500 lm. This high luminous flux is achieved due to the high efficacy of the aforementioned LEDs at high power density, which are able to emit more than 200 W/cm² at a current density of 200 A/cm² and at a junction temperature of 100° C. and higher.

FIG. 8 is a sketch 800 of an MR-16 lamp body embodiment used in LED lamps with improved quality of light. FIG. 8 shows an MR-16 lamp body 804, an optical lens 802, and an LED source that includes violet pump LEDs 808 and a phosphor mix 806 used in LED lamps with improved quality of light.

Depending on the details of the configuration, various embodiments may address one or several of the issues described above.

In order to reduce the SPD discrepancy in the blue-violet range, one needs to modify the LED lamp's spectral power distribution. The disclosed configurations achieve this by including violet pump LEDs. In an exemplary embodiment, these violet pump LEDs pump one blue phosphor. In some embodiments, the FWHM of the blue phosphor is more than 30 nm. In contrast to typical blue-pump LEDs (whose spectral FWHM is ˜20 nm), use of such a broad phosphor helps match the target SPD of a blackbody.

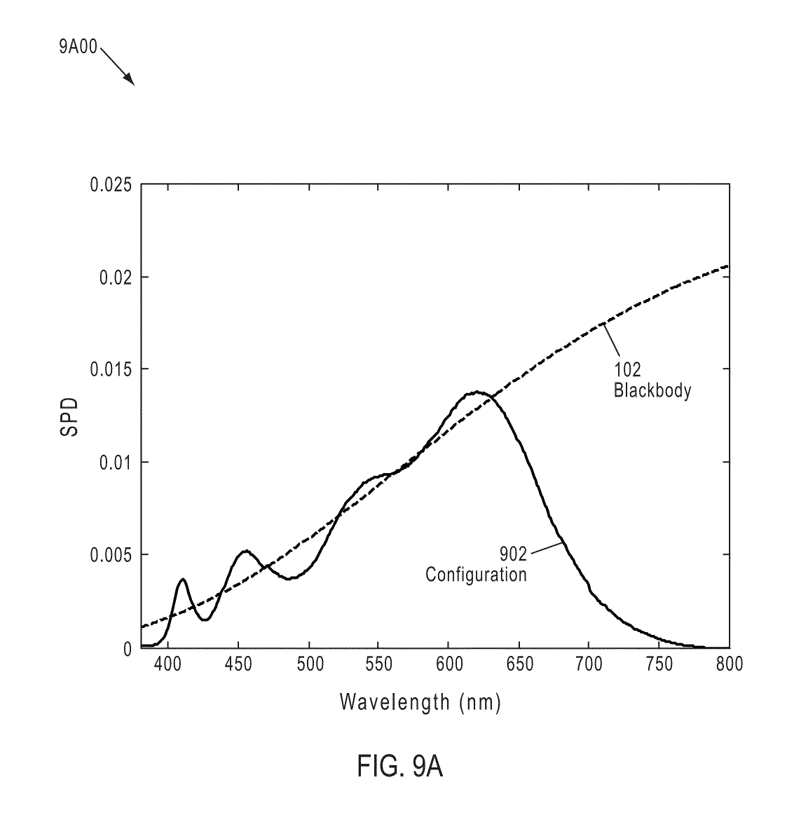

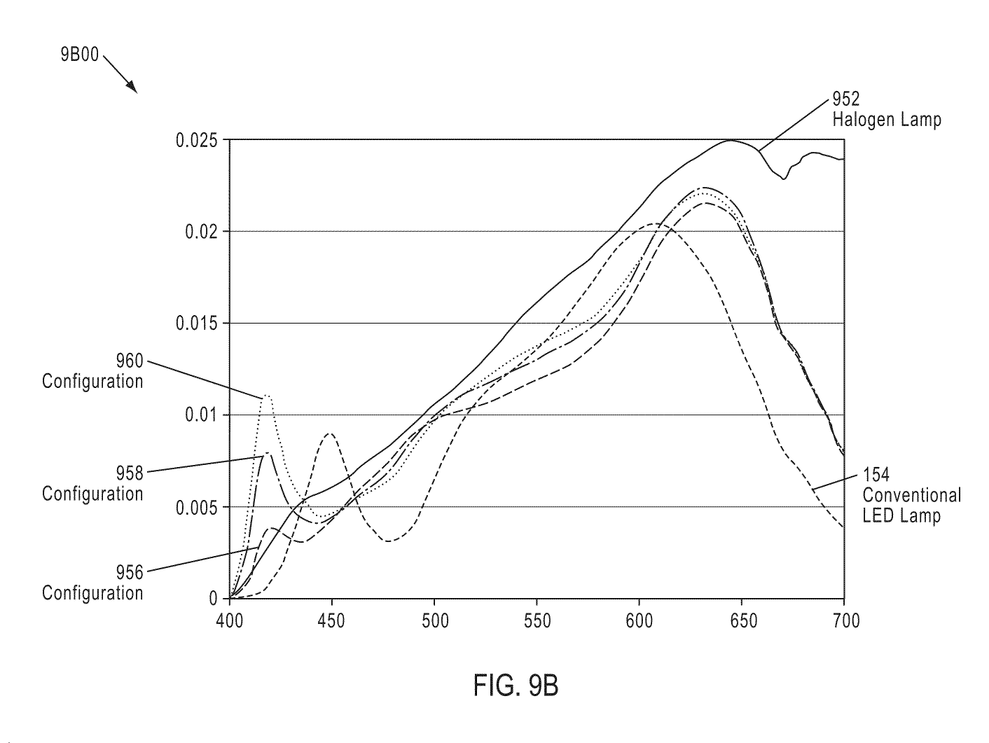

FIG. 9A is a chart 9A00 showing a comparison of modeled SPDs of a blackbody and an LED lamp with improved quality of light (see configuration 902).

FIG. 9A compares the SPD of an embodiment to that of a blackbody 102, both having a 3000K CCT and the same luminous flux. Compared to FIG. 1, the discrepancy is significantly reduced in the short-wavelength range.

FIG. 9B is a chart 9B00 showing the experimental SPDs of various illuminants.

FIG. 9B compares experimental SPDs of illuminants with a CCT of 3000K. The illuminants are a halogen lamp 952; a conventional LED lamp 154; and three embodiments shown as configuration 956, configuration 958, and configuration 960, where the violet leak is varied (with respective values of about 2%, 5% and 7%).

Embodiments with various violet leaks can be considered and optimized for a high CRI. For instance, the experiments have verified that an embodiment with about a 7% violet leak may have a CRI of about 95, an R9 of about 95, and a Large-sample set CRI of about 87. Other embodiments may lead to further improvements in these values.

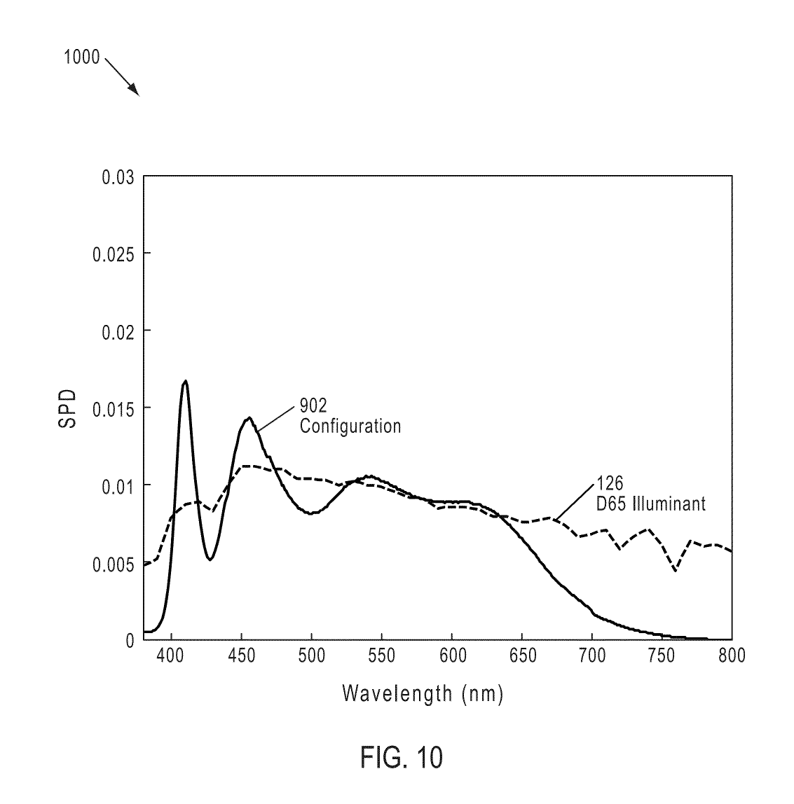

FIG. 10 is a chart 1000 showing a comparison of SPDs of a blackbody and LED lamps with improved quality of light.

FIG. 10 is similar to FIG. 9A, but here the reference illuminant D65 126 is for a 6500K CCT. The SPD dependence with respect to wavelength is also shown for configuration 902.

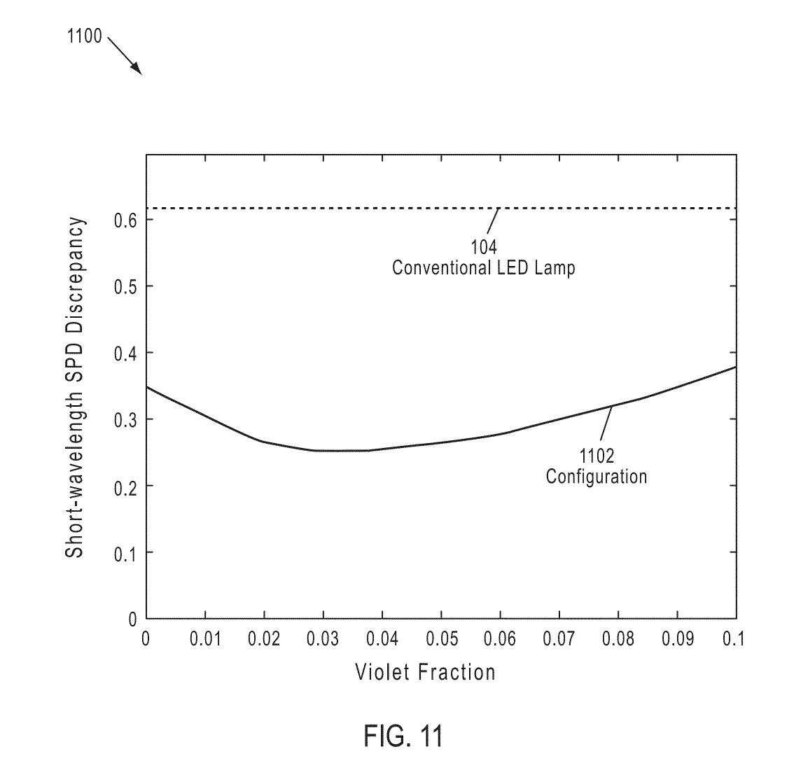

FIG. 11 is a chart 1100 showing the short-wavelength SPD discrepancy between a blackbody radiator and configuration 1102, both with a CCT of 3000K, as a function of the SPD violet fraction for comparing LED lamps with improved quality of light. The dashed line represents the value for a conventional LED-based source 104.

FIG. 11 shows the SWSD of embodiments with a 3000K CCT, as a function of the fraction of violet photons in the SPD. The SWSD is lower than for a conventional LED lamp 104 by a factor of two or more, depending on the violet fraction. Thus the violet fraction may be optimized to minimize SWSD, although other metrics may also be considered when choosing the violet fraction.

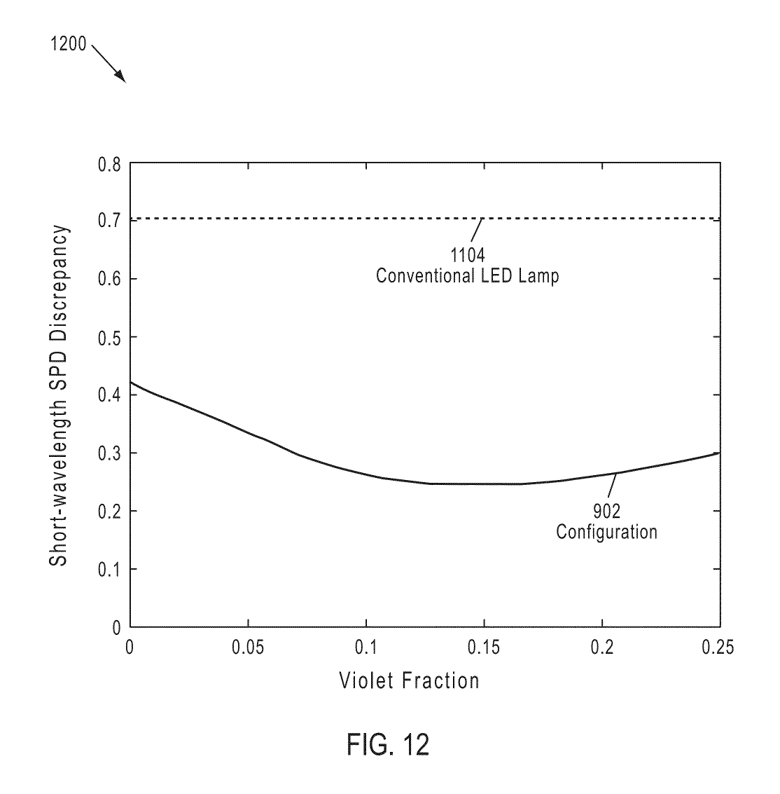

FIG. 12 is a chart 1200 showing the short-wavelength SPD discrepancy between a D65 illuminant and embodiments of the present disclosure, configuration 902, both with a CCT of 6500K, as a function of the SPD violet fraction for comparing LED lamps with improved quality of light. The dashed line represents the value for a conventional LED-based source 1104.

FIG. 12 shows the short-wavelength SPD discrepancy for a 6500K CCT. Here the reference illuminant is D65. Here again, the violet fraction may be optimized to minimize SWSD, although other metrics may also be considered when choosing the violet fraction.

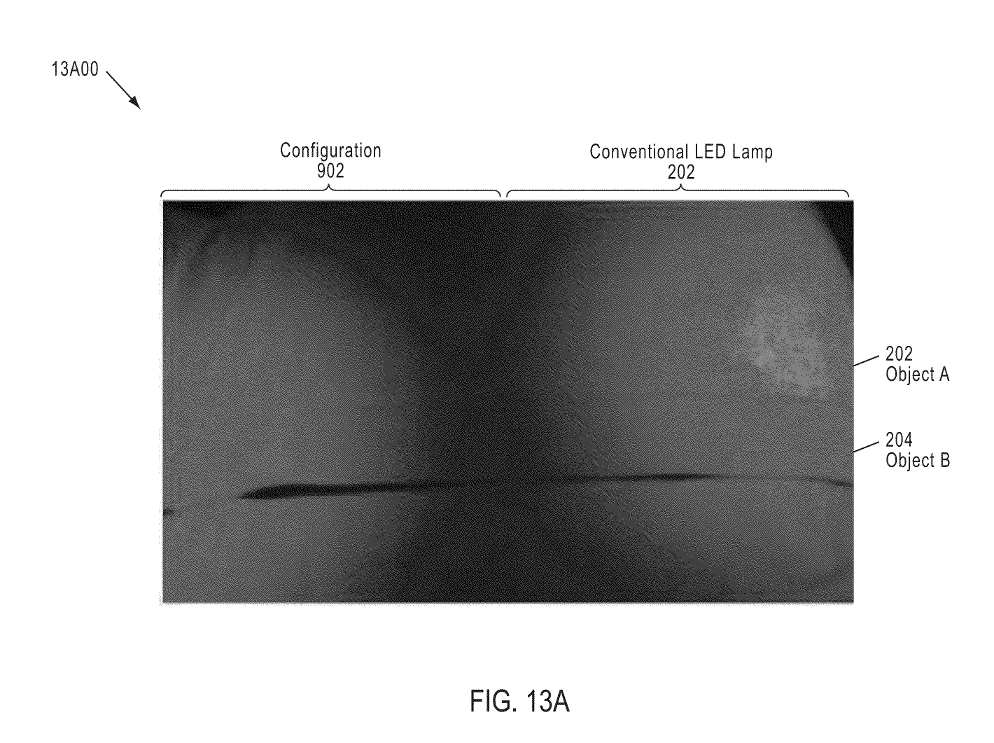

FIG. 13A is a picture 13A00 showing two reddish objects under illumination by a conventional LED source and by a particular configuration, both with a 2700K CCT. The objects (object A 202 and object B 204) are the same as depicted in FIG. 2A. Again, metamerism is apparent with the conventional LED source and the objects have different colors. With particular configuration of the embodiments as disclosed herein, the color is nearly identical for both objects, as it is under daylight illumination. FIG. 13A exemplifies how some embodiments of the invention can reduce metamerism and improve color rendering.

FIG. 13B is a sketch of FIG. 13A showing the two reddish objects under illumination by a conventional LED source (e.g., lamp 202), and by an example configuration 902, both with a 2700K CCT. Note the indication of color difference 1304 versus no color difference 1302. Again, metamerism is apparent with the conventional LED source—the objects appear to have different colors. On the other hand, when illuminated with lamps following embodiments as disclosed herein, the color is nearly identical for both objects (which is similar to appearance under daylight illumination). FIG. 13B exemplifies how some embodiments of the invention can reduce metamerism and improve color rendering.

In some embodiments, more than one phosphor in the blue-cyan range is pumped by the violet LED. In some embodiments, part of the blue emission comes from LEDs.

In order to improve the whiteness of objects containing OBAs, the LED-based source should emit a sufficient amount of light in the excitation range of the OBAs. The noted configurations achieve this by including violet pump LEDs. In an exemplary embodiment, 2% to 15% of the power of the resulting SPD is emitted in the range of 390 nm to 430 nm. In an exemplary embodiment, the violet LEDs pump one or several phosphors emitting in the blue-cyan range.

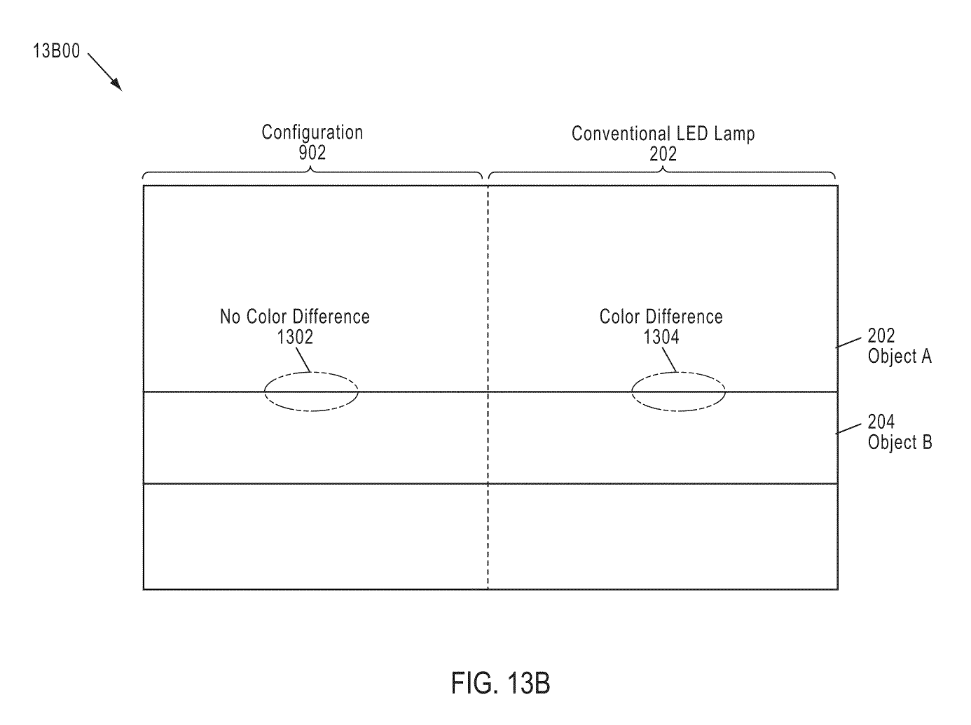

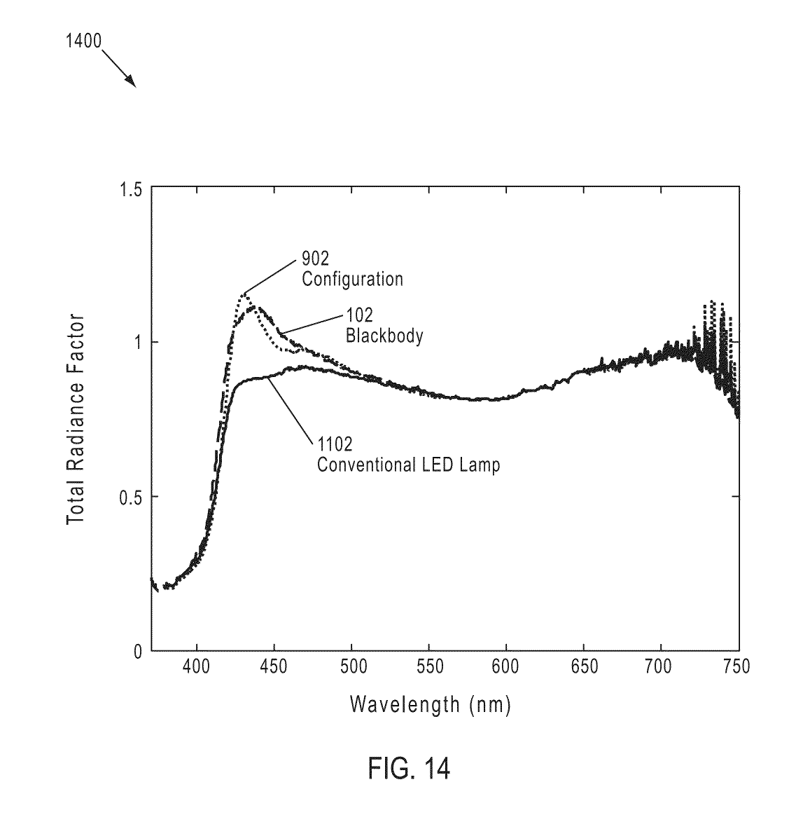

FIG. 14 is a chart 1400 showing the total radiance factor of a sample of white paper with optical brightening agents, for an incandescent source and a selected embodiment, both with a 3000K CCT for comparing LED lamps with improved quality of light.

FIG. 14 compares the experimental total radiance factors of a sheet of commercial white paper illuminated by a blackbody 102 radiator (in practice, a halogen lamp), a conventional LED lamp 1102, and an embodiment of the invention (configuration 902), all with the same CCT of 3000K. Unlike the conventional LED, the total radiance factor of the embodiment of the invention is similar to that of a blackbody source, due in part to the excitation of OBA fluorescence.

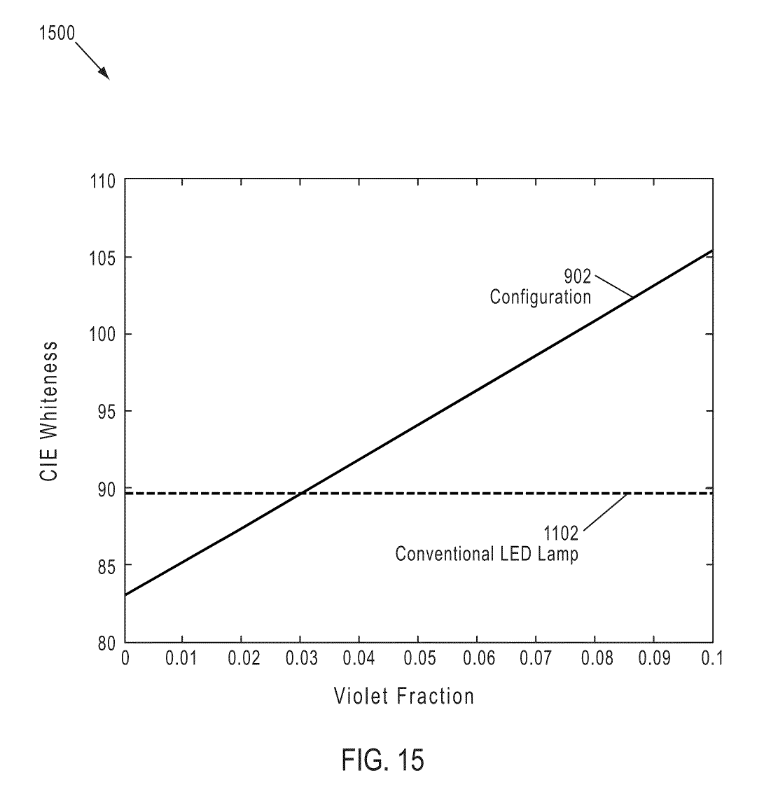

FIG. 15 is a chart 1500 showing the CIE whiteness of calculated sources with a 6500K CCT for comparisons of LED lamps with improved quality of light.

FIG. 15 displays the modeled CIE whiteness of a paper sheet as illuminated by various embodiments of the invention (configuration 902), where the amount of violet light in the SPD is varied. The improvement of whiteness can be significant. In this case, the CCT of the lamp is 6500K, in accordance with the definition of the CIE whiteness equation. The dashed line shows the CIE Whiteness for a conventional LED source.

In addition to tuning CIE whiteness by changing the amount of violet leak, it is also possible to affect CIE whiteness by changing the peak wavelength of the violet peak in some embodiments of the invention. For instance, in some embodiments the violet peak may have a maximum at 410 nm, 415 nm, or 420 nm. In general, OBAs have a soft absorption edge around 420 nm to 430 nm, so an embodiment with a violet peak beyond 420 nm may yield a lower optical excitation of OBAs.

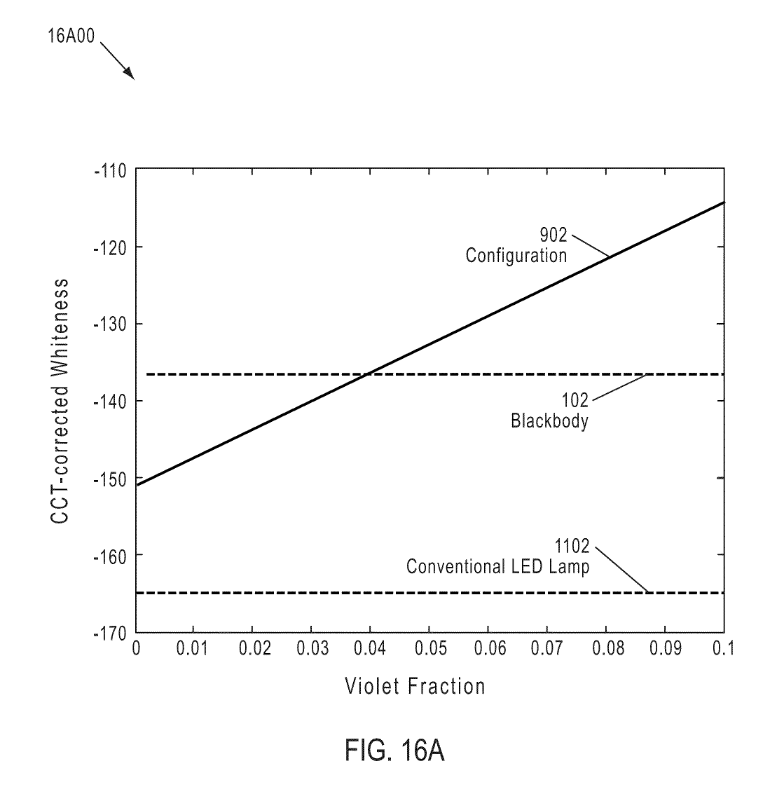

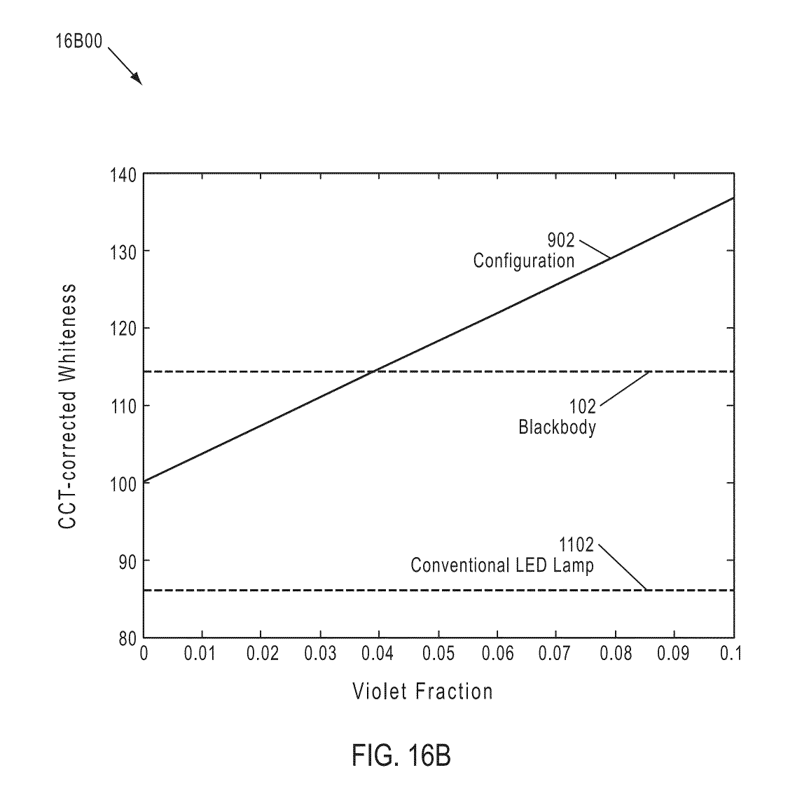

FIG. 16A is a chart 1600 showing the CIE whiteness of calculated sources with a 3000K CCT for comparisons of LED lamps with improved quality of light.

FIG. 16A shows a chart 1600 similar to the chart of FIG. 15, in the case where the CCT of the conventional LED lamp 1102 is 3000K. In this case, CIE whiteness is in principle not well-defined because using the equation yields negative values. However, one can still use CIE whiteness as a relative metric to quantify improvements in whiteness. As before, the whiteness is significantly improved by addition of a violet peak in the SPD. The dashed lines show the CIE Whiteness for a blackbody 102 and for a conventional LED lamp 1102, respectively.

FIG. 16B is a chart 1650 showing the CCT-corrected Whiteness of sources with a 3000K CCT for comparisons of LED lamps with improved quality of light. The CCT-corrected Whiteness is shown for an embodiment of the present disclsoure (configuration 902), a blackbody source 102, and for a conventional LED lamp 1102.

FIG. 16B shows CCT-corrected Whiteness rather than the CIE whiteness. Because the CCT of the illuminant is taken into account in the CCT-corrected Whiteness formula, the values are positive. As in FIG. 16A, whiteness is significantly improved when the violet leak is increased.

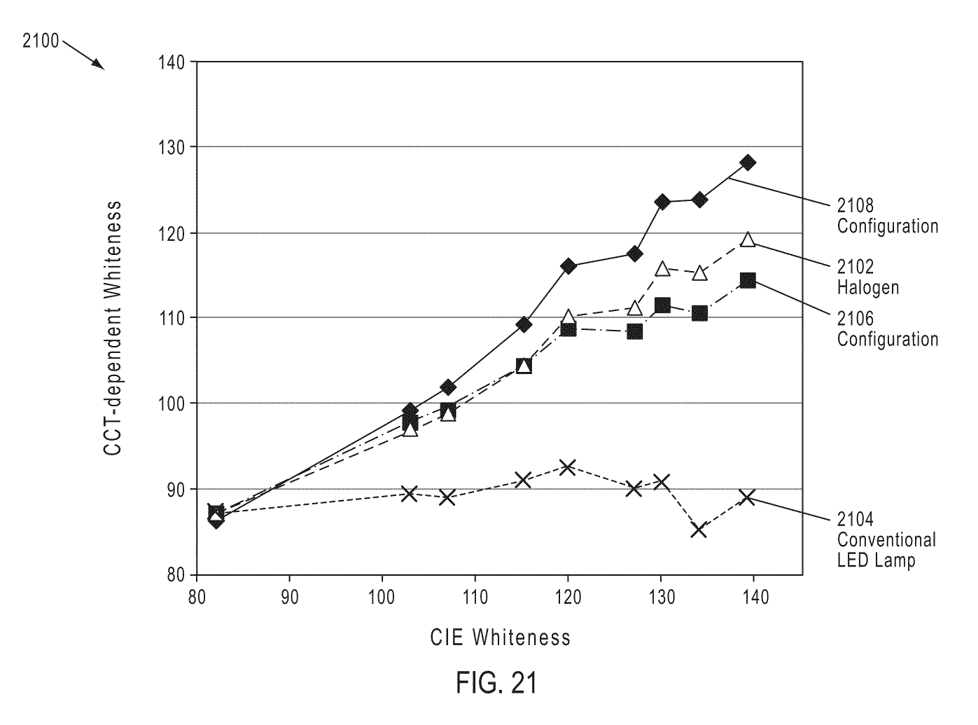

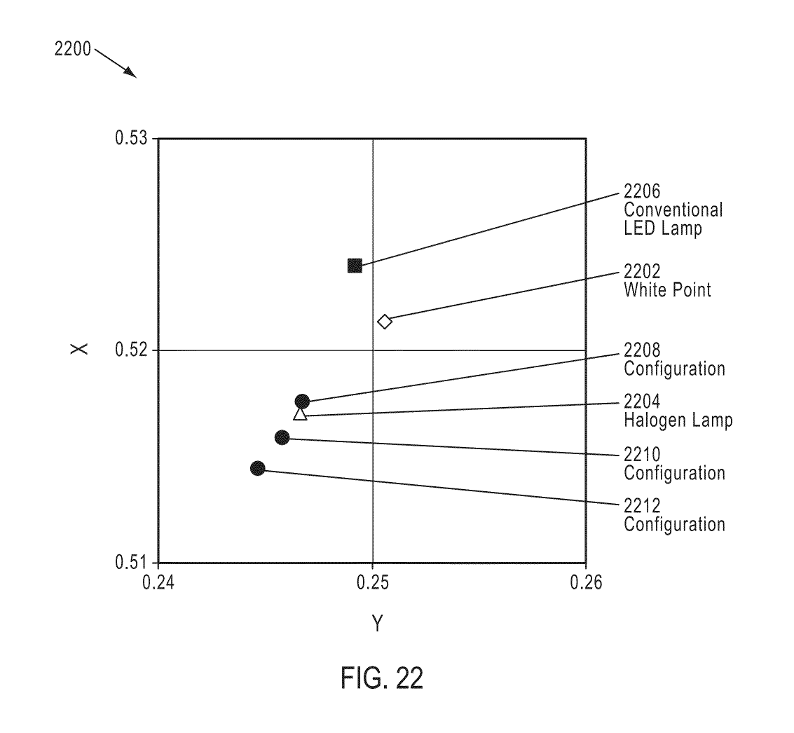

Empirical results for CCT-corrected Whiteness of various objects illuminated by various illuminants and coordinates of a high whiteness reference standard illuminated by various sources are given in FIG. 21 and FIG. 22, respectively.

One skilled in the art will recognize that optical excitation of OBAs can be used to induce enhanced whiteness. In addition, it should be recognized that this effect should not be over used, because a very large excitation of OBAs is perceived as giving a blue tint to an object, thus reducing perceived whiteness. For instance, numerous commercial objects have a CIE whiteness or a CCT-dependent Whiteness of about 110 to 140 under excitation by a halogen or a ceramic metal halide CMH source. Exceeding this design value by a large amount, for instance more than 40 points, is likely to result in an unwanted blue tint.

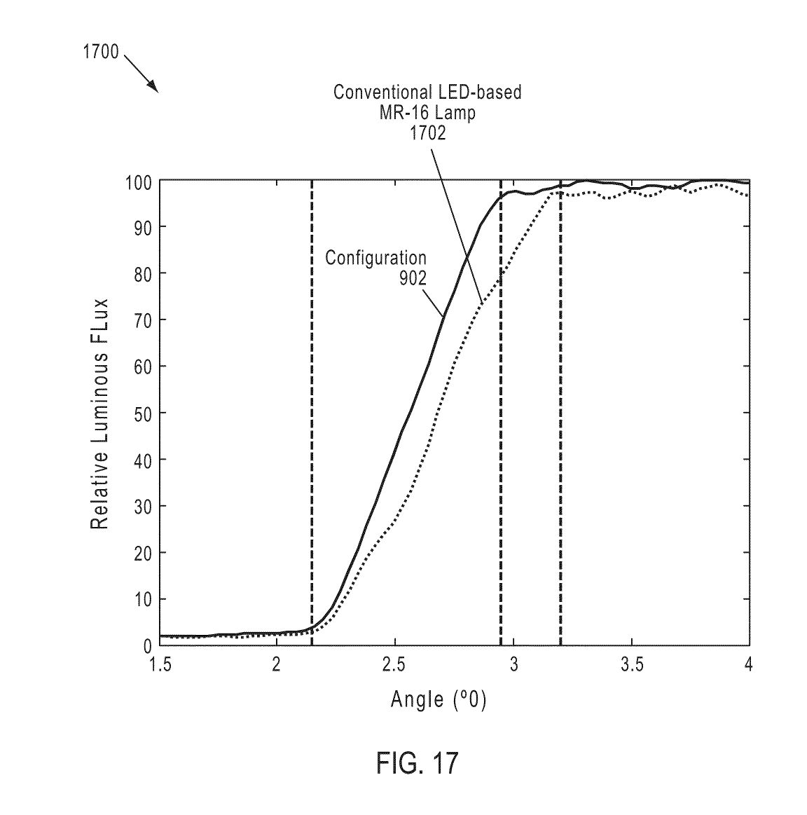

FIG. 17 is a chart 1700 showing the relative luminous flux across a projected shadow versus angle for a conventional LED-based MR-16 lamp 1702 and an embodiment of the present disclsoure (configuration 902) for comparisons of LED lamps with improved quality of light. The vertical dashed lines mark the beginning and end of the partial shadow regions.

In order to produce sharp object shadows, the source needs to have a limited spatial extension. Furthermore, it should produce a sufficient luminous flux for general lighting. Such a configuration is achieved by employing an LED source which has a small footprint and a high luminous flux, together with a small-footprint optical lens.

In exemplary embodiments, the area of the LED source is less than 13 mm², or less than 29 mm². In exemplary embodiments, the light emitted by the LED source is redirected or collimated by a lens whose lateral extension is smaller than 40 mm.

FIG. 17 shows an experimental measurement of a shadow cast by an embodiment of the invention with the setup of FIG. 6. The angular width of the partial shadow region is less than 0.8°.

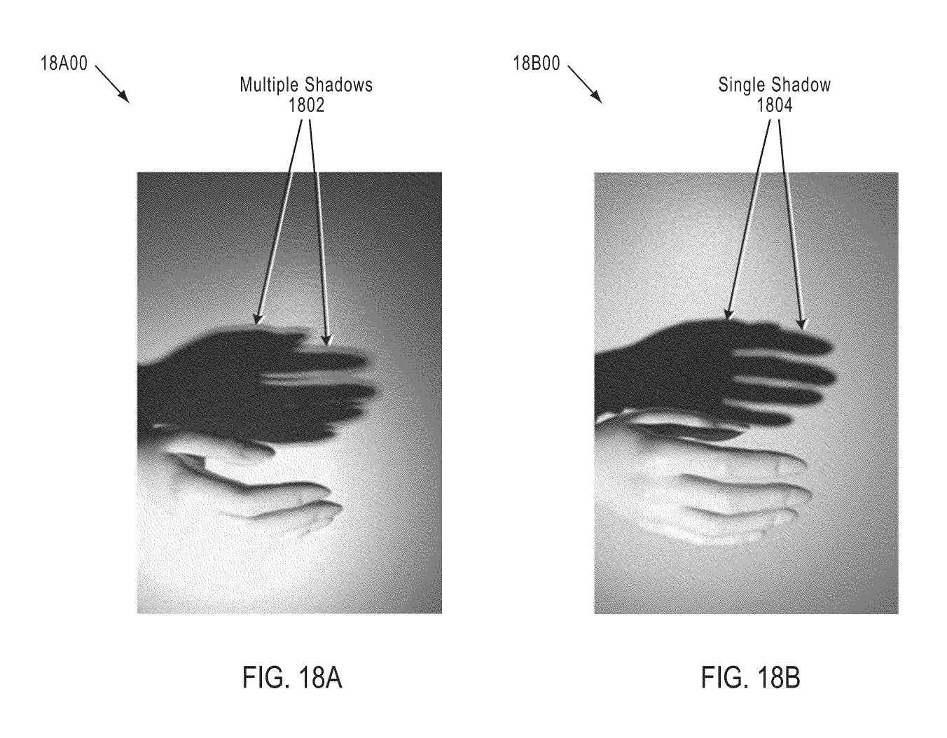

FIG. 18A is a picture 18A00 of multiple shadows cast by a hand, under illumination by a conventional LED lamp with multiple light sources, for comparison with an LED source with improved quality of light.

FIG. 18A shows how a multiple-source LED can be detrimental to shadow rendering. Each source casts a shadow, resulting in a multiple and blurry shadow. The separation between the fingers is barely visible in the shadow.

FIG. 18B is a picture 18B00 showing the shadow cast by a hand under illumination by an embodiment of the invention.

In FIG. 18B, the shadow is well-defined. The fingers are clearly separated. This illustrates how a single source with a reduced lateral extent can improve shadow rendering.

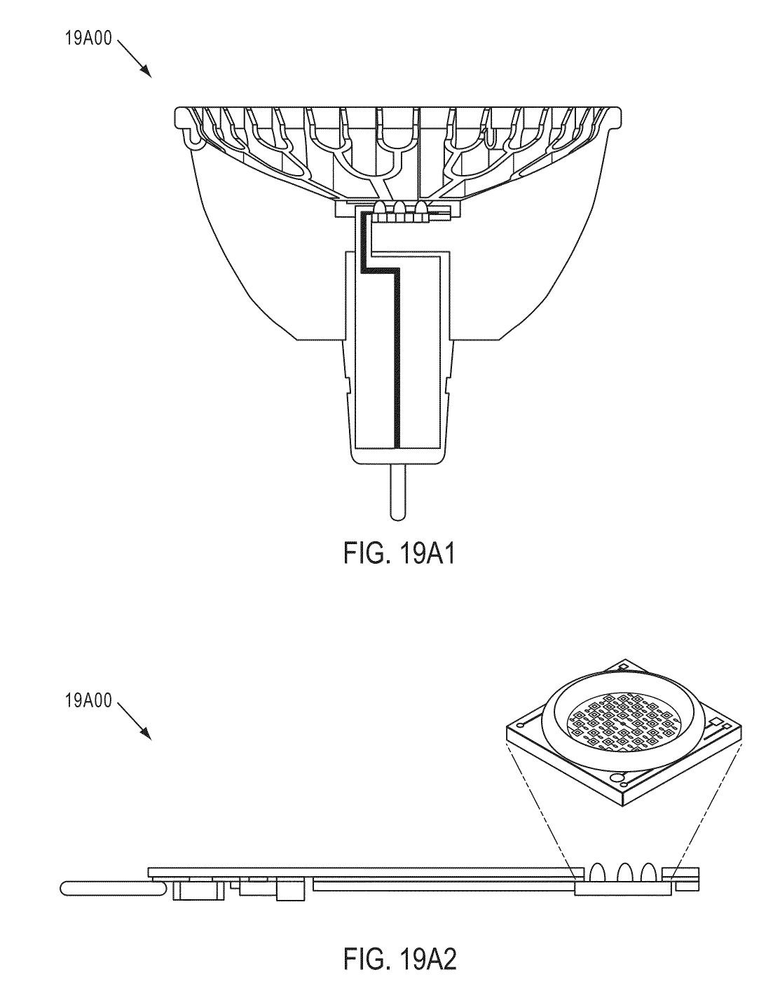

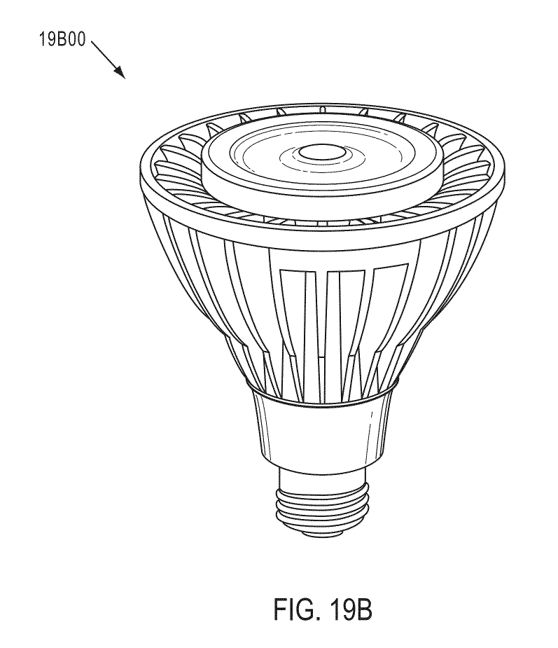

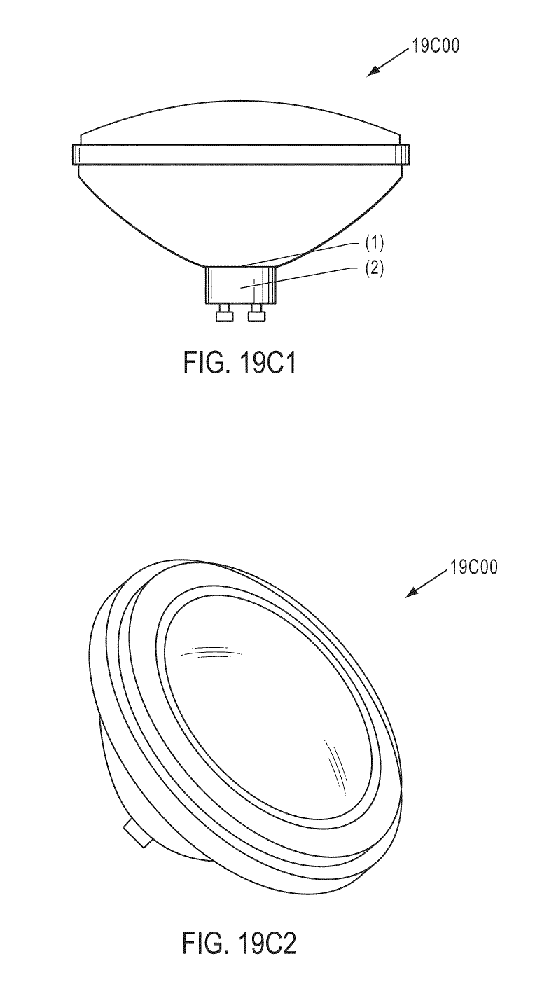

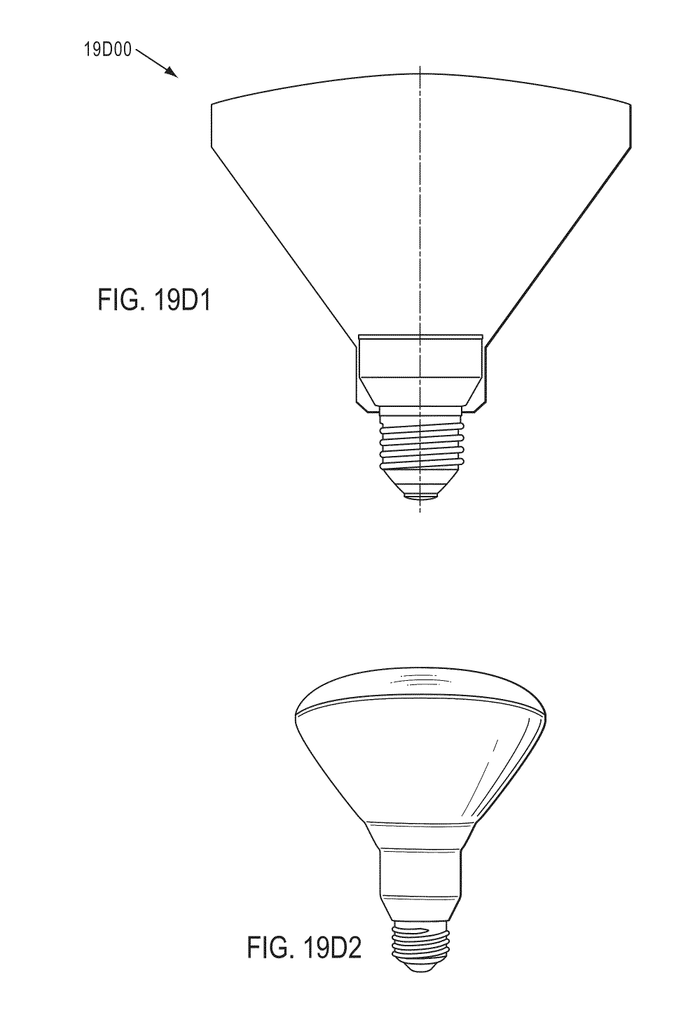

FIG. 19A depicts an MR-16 form factor 19A00 used in LED lamps with improved quality of light.

There are many configurations of LED lamps and of contacts. For example Table 2 gives standards (see “Designation”) and corresponding characteristics.

TABLE 3

| | Base | | |
|---|---|---|---|
| | Diameter | | IEC 60061-1 |
| | (crest of | | Standard |
| Designation | thread) | Name | Sheet |
| E05 | 05 mm | Lilliput Edison Screw (LES) | 7004-25 |
| E10 | 10 mm | Miniature Edison Screw (MES) | 7004-22 |
| E11 | 11 mm | Mini-Candelabra Edison Screw | (7004-06-1) |
| | | (mini-can) | |
| E12 | 12 mm | Candelabra Edison Screw (CES) | 7004-28 |
| E14 | 14 mm | Small Edison Screw (SES) | 7004-23 |
| E17 | 17 mm | Intermediate Edison Screw (IES) | 7004-26 |
| E26 | 26 mm | [Medium] (one-inch) Edison | 7004-21A-2 |
| | | Screw (ES or MES) | |
| E27 | 27 mm | [Medium] Edison Screw (ES) | 7004-21 |
| E29 | 29 mm | [Medium] Edison Screw (ES) | |
| E39 | 39 mm | Single-contact (Mogul) Giant | 7004-24-A1 |
| | | Edison Screw (GES) | |
| E40 | 40 mm | (Mogul) Giant Edison Screw | 7004-24 |
| | | (GES) | |

Additionally, a base member (e.g., shell, casing, etc.) can be of any form factor configured to support electrical connections, which electrical connections can conform to any of a set of types or standards. For example Table 3 gives standards (see “Type”) and corresponding characteristics, including mechanical spacings between a first pin (e.g., a power pin) and a second pin (e.g., a ground pin).

TABLE 4

| | | Pin (center | | | | |
|---|---|---|---|---|---|---|
| Type | Standard | to center) | | Pin Diameter | | Usage |
| G4 | IEC 60061-1 | 4.0 | mm | 0.65-0.75 | mm | MR11 and other small halogens of |
| | (7004-72) | | | | | 5/10/20 watt and 6/12 volt |
| GU4 | IEC 60061-1 | 4.0 | mm | 0.95-1.05 | mm | |
| | (7004-108) | | | | | |
| GY4 | IEC 60061-1 | 4.0 | mm | 0.65-0.75 | mm | |
| | (7004-72A) | | | | | |
| GZ4 | IEC 60061-1 | 4.0 | mm | 0.95-1.05 | mm | |
| | (7004-64) | | | | | |
| G5 | IEC 60061-1 | 5 | mm | | | T4 and T5 fluorescent tubes |
| | (7004-52-5) | | | | | |
| G5.3 | IEC 60061-1 | 5.33 | mm | 1.47-1.65 | mm | |
| | (7004-73) | | | | | |
| G5.3-4.8 | IEC 60061-1 | 5.33 | mm | 1.45-1.6 | mm | |
| | (7004-126-1) | | | | | |
| GU5.3 | IEC 60061-1 | | | | | |
| | (7004-109) | | | | | |
| GX5.3 | IEC 60061-1 | 5.33 | mm | 1.45-1.6 | mm | MR-16 and other small halogens |
| | (7004-73A) | | | | | of 20/35/50 watt and 12/24 volt |
| GY5.3 | IEC 60061-1 | | | 5.33 | mm | |
| | (7004-73B) | | | | | |
| G6.35 | IEC 60061-1 | 6.35 | mm | 0.95-1.05 | mm | |
| | (7004-59) | | | | | |
| GX6.35 | IEC 60061-1 | 6.35 | mm | 0.95-1.05 | mm | |
| | (7004-59) | | | | | |
| GY6.35 | IEC 60061-1 | 6.35 | mm | 1.2-1.3 | mm | Halogen 100 W 120 V |
| | (7004-59) | | | | | |
| GZ6.35 | IEC 60061-1 | 6.35 | mm | 0.95-1.05 | mm | |
| | (7004-59A) | | | | | |
| G8 | | 8.0 | mm | | | Halogen 100 W 120 V |
| GY8.6 | | 8.6 | mm | | | Halogen 100 W 120 V |
| G9 | IEC 60061-1 | 9.0 | mm | | | Halogen 120 V (US)/230 V (EU) |
| | (7004-129) | | | | | |
| G9.5 | | 9.5 | mm | 3.10-3.25 | mm | Common for theatre use, several |
| | | | | | | variants |
| GU10 | | 10 | mm | | | Twist-lock 120/230-volt MR-16 |
| | | | | | | halogen lighting of 35/50 watt, |
| | | | | | | since mid-2000 s |
| G12 | | 12.0 | mm | 2.35 | mm | Used in theatre and single-end |
| | | | | | | metal halide lamps |
| G13 | | 12.7 | mm | | | T8 and T12 fluorescent tubes |
| G23 | | 23 | mm | 2 | mm | |
| GU24 | | 24 | mm | | | Twist-lock for self-ballasted |
| | | | | | | compact fluorescents, since 2000 s |
| G38 | | 38 | mm | | | Mostly used for high-wattage |
| | | | | | | theatre lamps |
| GX53 | | 53 | mm | | | Twist-lock for puck-shaped under- |
| | | | | | | cabinet compact fluorescents, |
| | | | | | | since 2000 s |

FIG. 19B depicts a PAR30 form factor lamp 19B00 used in LED lamps with improved quality of light.

FIG. 19C1 and FIG. 19C2 depicts AR111 form factors 19C00 used in LED lamps with improved quality of light.

FIG. 19D1 and 19D2 depicts PAR38 form factors 19D00 used in LED lamps with improved quality of light.

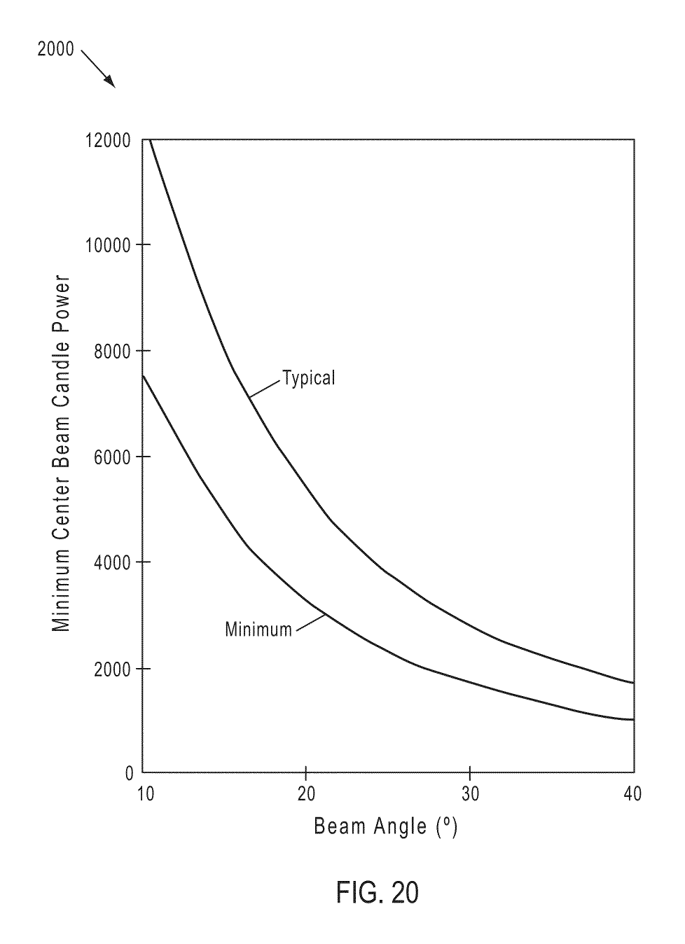

FIG. 20 is a chart 2000 that indicates the center beam candle power requirements for 50-watt MR-16 lamps as a function of the beam angle. For a typical application, such as a 25° beam angle, a center beam candle power of at least 2200 candelas is required.

FIG. 21 is a chart 2100 showing the experimentally-measured CCT-corrected Whiteness of various objects illuminated by various illuminants for comparison to LED lamps with improved quality of light.

The various plotted objects in FIG. 21 correspond to a series of nine whiteness standards sold by Avian Technologies containing a varied amount of OBAs. The CIE Whiteness of these standards increases with the amount of OBA. The sample with the highest amount of OBA, which reference number is AT-FTS-17a, has a CIE whiteness of about 140 and is referred to as a “high whiteness reference sample”. The x-axis of the chart 2100 indicates the CIE whiteness of these standards (under D65 illumination). The plotted objects correspond to experimentally measured values. The y-axis of the chart indicates the corresponding CCT-corrected Whiteness under various illuminants, as measured experimentally. The illuminants include a halogen lamp 2102; a conventional LED lamp 2104; a configuration 2106 with a 6% violet leak, and a configuration 2108 with a 10% violet leak. The conventional LED lamp 2104 fails to excite fluorescence from the OBAs, therefore the CCT-corrected Whiteness is roughly the same (about 86) for all of the shown illuminants. The halogen lamp 2102, configuration 2106 and configuration 2108 show increased CCT-corrected Whiteness for the standards having a higher CIE whiteness. The halogen lamp and configuration 2106 have very similar values of CCT-corrected Whiteness. Configuration 2108 has higher values of CCT-corrected Whiteness. This chart shows that, depending on the amount of violet leak, perceived whiteness can be tuned to match or exceed that of another illuminant (such as a halogen lamp).

FIG. 22 is a chart 2200 showing the (x,y) colorspace coordinates of a high whiteness reference standard illuminated by various sources with a 3000K CCT for comparisons of LED lamps with improved quality of light.

FIG. 22 shows the (x,y) colorspace coordinates of various points. The white point 2202 for an illuminant with a CCT of 3000K is shown. The experimental color coordinates of a high whiteness reference standard, illuminated by several illuminants, are also shown. The illuminants are a halogen lamp 2204, a conventional LED lamp 2206, a configuration of the invention with a 6% violet leak 2208, a configuration of the invention with an 8% violet leak 2210, and a configuration of the invention with a 10%-violet leak 2212. The (x,y) color shift (with respect to the white point 2202) is in a similar direction, and of a similar magnitude, for the halogen lamp and the three configurations of the invention. This confirms that all these illuminants induce a similar whiteness enhancement. On the other hand, the (x,y) color shift is smaller and in a different direction for the conventional LED lamp 2206; this is because no OBA fluorescence is induced (e.g., the small shift is due to the slight tint of the reference sample).

These shifts in chromaticity can be summarized as a series of Duv values from the illuminant's white point—e.g. for each illuminant, the chromaticity of the high-whiteness reference sample is characterized and its distance Duv from the illuminant's white point is calculated. Table 5 is a table that shows the Duv values for various illuminants with a CCT of 3000K, and specifies the direction of the color shift (either toward the blue direction or away from the blue direction). As can be seen, sources which are able to excite significant whiteness are characterized by Duv values of about five and more toward the blue direction. In contrast, a conventional blue-based LED source has a Duv of about 3 away from the blue direction. In Table 5, two configurations of the invention are shown. Configuration 1 has a violet leak of 6%, and configuration 2 has a violet leak of 10%.

TABLE 5

| | | Blue- | | |
|---|---|---|---|---|
| | Halogen | pumped | | |
| | source | LED | Configuration 1 | Configuration 2 |
| Duv | 5.7 | 2.7 | 5.2 | 9.0 |
| Direction with | toward | away form | toward | toward |
| respect to blue | | | | |

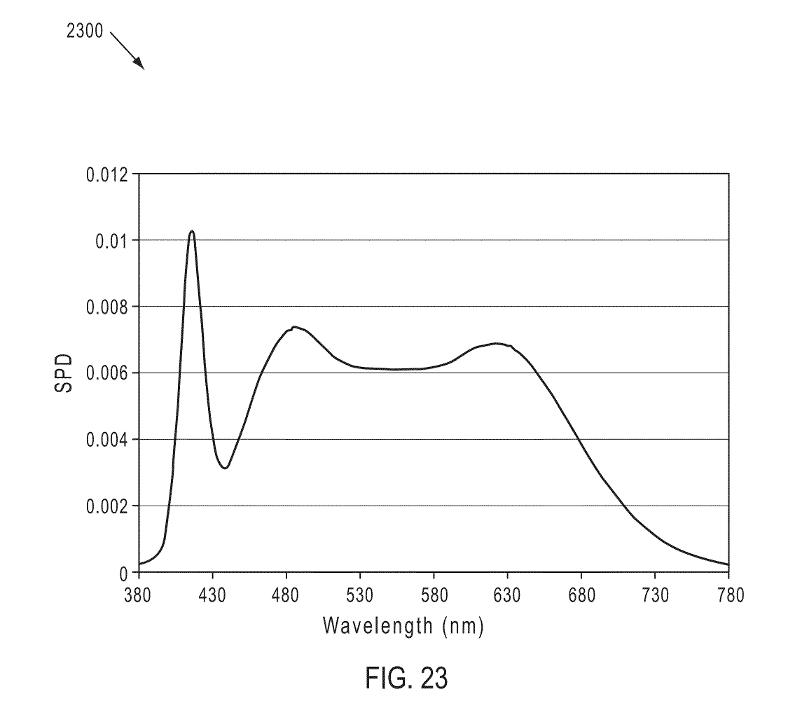

FIG. 23 is a chart 2300 showing the experimental SPD of an LED lamp with improved quality of light.

FIG. 23 is an experimental spectrum of an embodiment. It has a CCT of 5000K, a CRI value higher than 95, an R9 value higher than 95, and about 11% violet leak.

As a consequence, it is desirable to configure an LED-based lamp which is useful for general illumination purposes, and which improves on the quality-of-light limitations described above.

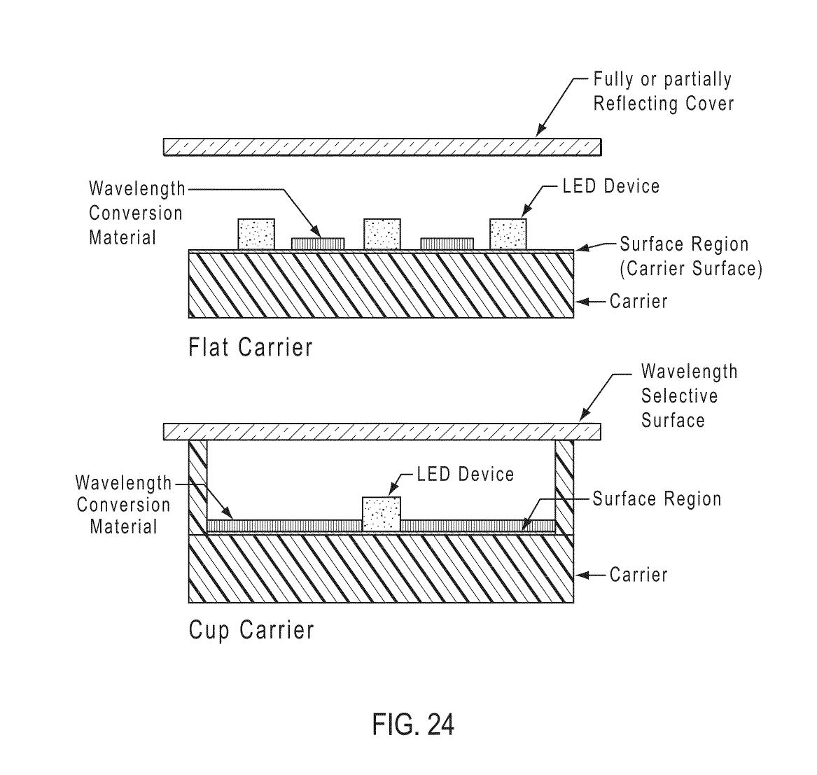

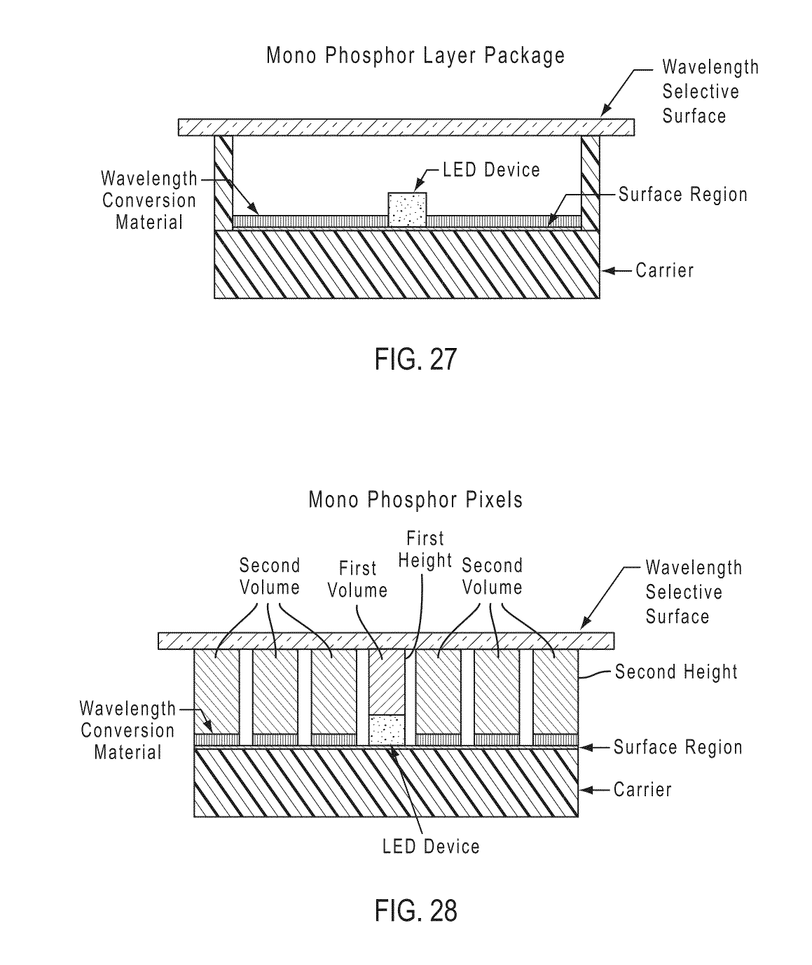

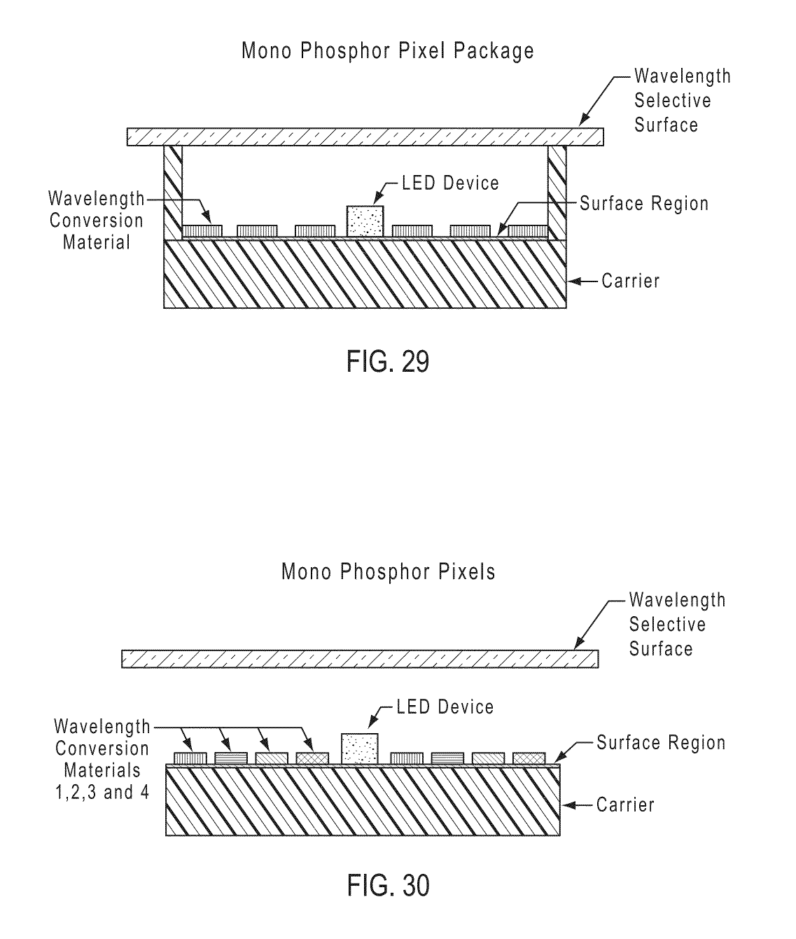

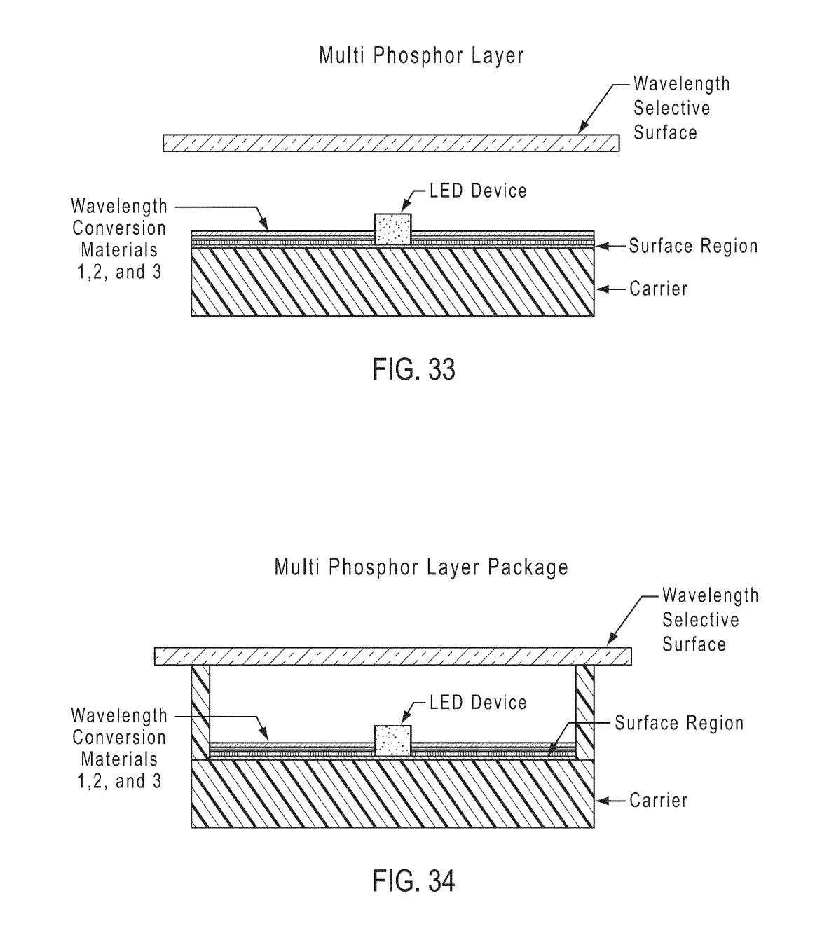

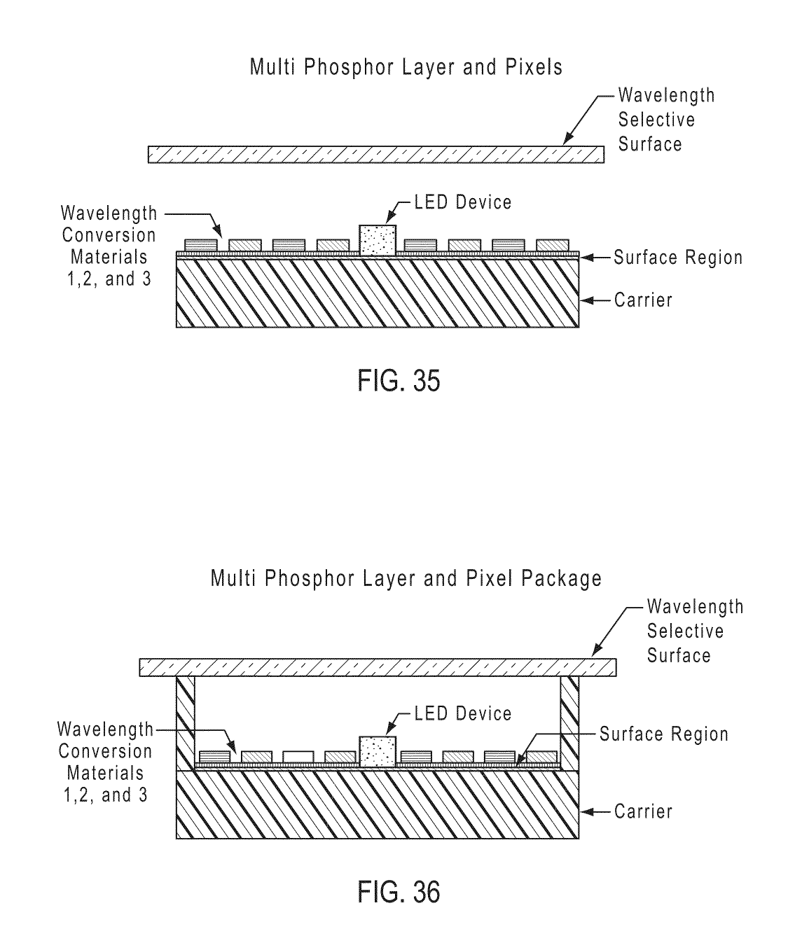

In certain embodiments, LED devices provided by the present disclosure include the embodiments shown in FIGS. 24 to 36.

Of particular importance to the field of lighting is the progress of light emitting diodes (LED) fabricated on nonpolar and semipolar GaN substrates. Such devices making use of InGaN light emitting layers have exhibited record output powers at extended operation wavelengths into the violet region (390-430 nm), the blue region (430-490 nm), the green region (490-560 nm), and the yellow region (560-600 nm). For example, a violet LED, with a peak emission wavelength of 402 nm, was recently fabricated on an m-plane (1-100) GaN substrate and demonstrated greater than 45% external quantum efficiency, despite having no light extraction enhancement features, and showed excellent performance at high current densities, with minimal roll-over. With high-performance bulk-GaN-based LEDs, several types of white light sources are now possible. In one implementation, a violet-emitting bulk-GaN-based LED is packaged together with phosphors. Preferably, the phosphor is a blend of three phosphors, emitting in the blue, the green, and the red, or sub-combinations thereof.

A polar, non-polar or semi-polar LED may be fabricated on a bulk gallium nitride substrate. The gallium nitride substrate is usually sliced from a boule that was grown by hydride vapor phase epitaxy or ammonothermally, according to methods known in the art. The gallium nitride substrate can also be fabricated by a combination of hydride vapor phase epitaxy and ammonothermal growth, as disclosed in U.S. Patent Application No. 61/078,704, commonly assigned, and hereby incorporated by reference. The boule may be grown in the c-direction, the m-direction, the a-direction, or in a semi-polar direction on a single-crystal seed crystal. Semipolar planes may be designated by (hkil) Miller indices, where i=−(h+k), l is nonzero and at least one of h and k are nonzero. The gallium nitride substrate may be cut, lapped, polished, and chemical-mechanically polished. The gallium nitride substrate orientation may be within ±5 degrees, ±2 degrees, ±1 degree, or ±0.5 degrees of the {1 −1 0 0} m plane, the {1 1 −2 0} a plane, the {1 1 −2 2} plane, the {2 0 −2±1} plane, the {1 −1 0±1} plane, the {1 −1 0 −±2} plane, or the {1 −1 0±3} plane. The gallium nitride substrate preferably has a low dislocation density.

A homoepitaxial polar, non-polar or semi-polar LED is fabricated on the gallium nitride substrate according to methods that are known in the art, for example, following the methods disclosed in U.S. Pat. No. 7,053,413, which is hereby incorporated by reference in its entirety. At least one AlₓIn_{y}Ga_{1-x-y}N layer, where 0≦x≦1, 0≦y≦1, and 0≦x+y≦1, is deposited on the substrate, for example, following the methods disclosed by U.S. Pat. Nos. 7,338,828 and 7,220,324, which are hereby incorporated by reference in their entirety. The at least one AlₓIn_{y}Ga_{1-x-y}N layer may be deposited by metal-organic chemical vapor deposition, by molecular beam epitaxy, by hydride vapor phase epitaxy, or by a combination thereof. The AlₓIn_{y}Ga_{1-x-y}N layer comprises an active layer that preferentially emits light when an electrical current is passed through it. The active layer can be a single quantum well, with a thickness between about 0.5 nm and about 40 nm. In another embodiment, the active layer is a multiple quantum well, or a double heterostructure, with a thickness between about 40 nm and about 500 nm. In one specific embodiment, the active layer comprises an In_{y}Ga_{1-y}N layer, where 0≦y≦1.

The invention provides packages and devices including at least one LED placed on a mounting member. In other embodiments, the starting materials can include polar gallium nitride containing materials and others, such as sapphire, aluminum nitride, silicon, silicon carbide, and other substrates. The present packages and devices are preferably combined with phosphors to discharge white light.

FIG. 24 is a diagram of a flat carrier packaged light emitting device 100 and recessed or cup packaged light emitting device 110. The invention provides a packaged light emitting device configured in a flat carrier package 100. As shown, the device has a mounting member with a surface region. The mounting member is made of a suitable material such a ceramics, semiconductors (e.g., silicon), metal (aluminum, Alloy 42 or copper), plastics, dielectrics, and the like. The substrate may be provided as a lead frame member, a carrier or other structure. These are collectively referred to as “substrate” in the drawings.

The mounting member, which holds the LED, can come in various shapes, sizes, and configurations. Usually the surface region of the mounting member is substantially flat, although there may be one or more slight variations the surface region, for example, the surface can be cupped or terraced, or a combinations of the flat and cupped shapes. Additionally, the surface region generally has a smooth surface, plating, or coating. Such plating or coating can be gold, silver, platinum, aluminum, dielectric with metal thereon, or other material suitable for bonding to an overlying semiconductor material.

Referring again to FIG. 24, the optical device has light emitting diodes overlying the surface region. The light emitting diode devices 103 can be any type of LED, but in the preferred embodiment are preferably fabricated on a semipolar or nonpolar GaN containing substrate, but can be fabricated on polar gallium and nitrogen containing material. Preferably, the LED emits polarized electromagnetic radiation 105. The light emitting device is coupled to a first potential, which is attached to the substrate, and a second potential 109, which is coupled to wire or lead 111 bonded to a light emitting diode.

The light emitting diode device can be a blue-emitting LED device and the substantially polarized emission is blue light from about 440 nanometers to about 490 nanometers wavelength. In specific embodiments, a {1 −1 0 0} m-plane bulk substrate or a {1 0 −1 −1} semi-polar bulk substrate is used for the semipolar blue LED. The substrate has a flat surface, with a root-mean-square (RMS) roughness of about 0.1 nm, a threading dislocation density less than 5×10⁶ cm⁻², and a carrier concentration of about 1×10¹⁷ cm⁻³. Epitaxial layers are deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth is between about 3000 and about 12000. First, a contact layer of n-type (silicon-doped) GaN is deposited on the substrate, with a thickness of about 5 microns and a doping level of about 2×10¹⁸ cm⁻³. Next, an undoped InGaN/GaN multiple quantum well (MQW) is deposited as the active layer. The MQW superlattice has six periods, comprising alternating layers of 8 nm of InGaN and 37.5 nm of GaN as the barrier layers. Then, a 10 nm undoped AlGaN electron blocking layer is deposited. Finally, a p-type GaN contact layer is deposited, with a thickness of about 200 nm and a hole concentration of about 7×10¹⁷ cm⁻³. Indium tin oxide (ITO) is e-beam evaporated onto the p-type contact layer as the p-type contact and rapid-thermal-annealed. LED mesas, with a size of about 300×300 μm², are formed by photolithography and dry etching using a chlorine-based inductively-coupled plasma (ICP) technique. Ti/Al/Ni/Au is e-beam evaporated onto the exposed n-GaN layer to form the n-type contact, Ti/Au is e-beam evaporated onto a portion of the ITO layer to form a p-contact pad, and the wafer is diced into discrete LED dies. Electrical contacts are formed by conventional wire bonding.

In a specific embodiment, the optical device has a 100 micron or less thickness of material formed on an exposed portion of the surface region separate from the LEDs. The material includes wavelength conversion materials that convert electromagnetic radiation reflected off the wavelength selective reflector. Typically the material is excited by the LED emission and emits electromagnetic radiation of second wavelengths. In a preferred embodiment, the material emits substantially green, yellow, and or red light from an interaction with the blue light.

The entities preferably comprise phosphors or phosphor blends selected from (Y, Gd, Tb, Sc, Lu, La)₃(Al, Ga, In)₅O₁₂:Ce³⁺, SrGa₂S₄:Eu²⁺, SrS:Eu²⁺, and colloidal quantum dot thin films comprising CdTe, ZnS, ZnSe, ZnTe, CdSe, or CdTe. In other embodiments, the device includes a phosphor capable of emitting substantially red light. Such phosphor is selected from one or more of (Gd,Y,Lu,La)₂O₃:Eu³⁺,Bi³⁺; (Gd,Y,Lu,La)₂O₂S:Eu³⁺,Bi³⁺; (Gd,Y,Lu,La)VO₄:Eu³⁺, Bi³⁺; Y₂(O,S)₃:Eu³⁺; Ca₁₋ₓMo_{1-y}Si_{y}O₄: where 0.05≦x≦0.5, 0≦y≦0.1; (Li,Na,K)₅Eu(W,Mo)O₄; (Ca,Sr)S:Eu²⁺; SrY₂S₄:Eu²⁺; CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgxP₂O₇:Eu²⁺, Mn²⁺; (Y,Lu)₂WO₆:Eu³⁺, Mo⁶⁺; (Ba,Sr,Ca)₃MgxSi₂O₈:Eu²⁺, Mn²⁺, wherein 1<x≦2; (RE_{1-y}Ce_{y})Mg₂₋ₓLiₓSi₃₋ₓPₓO₁₂, where RE is at least one of Sc, Lu, Gd, Y, and Tb, 0.0001<x<0.1 and 0.001<y<0.1; (Y, Gd, Lu, La)₂₋ₓEuₓW_{1-y}Mo_{y}O₆,where 0.5≦x.≦1.0, 0.01≦y≦1.0; (SrCa)₁₋ₓEuₓSi₅N₈, where 0.01≦x≦0.3; SrZnO₂:Sm⁺³; MₘOₙX wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

Quantum dot materials comprise a family of semiconductor and rare earth doped oxide nanocrystals whose size and chemistry determine their luminescent characteristics. Typical chemistries for the semiconductor quantum dots include well known (ZnxCd1-x)Se [x=0 . . . 1], (Znx,Cd1-x)Se[x=0 . . . 1], Al(AsxP1-x) [x=0 . . . 1], (Znx,Cd1-x)Te[x=0 . . . 1], Ti(AsxP1-x) [x=0 . . . 1], In(AsxP1-x) [x=0 . . . 1], (AlxGa1-x)Sb [x=0 . . . 1], (Hgx,Cd1-x)Te[x=0 . . . 1] zincblende semiconductor crystal structures. Published examples of rare-earth doped oxide nanocrystals include Y₂O₃. Sm³⁺, (Y,Gd)₂O₃:Eu³⁺, Y₂O₃:Bi, Y₂O₃:Tb, Gd₂SiO₅:Ce, Y₂SiO₅:Ce, Lu₂SiO₅:Ce, Y₃Al₅)₁₂:Ce but should not exclude other simple oxides or orthosilicates. Many of these materials are being actively investigated as suitable replacement for the Cd and Te containing materials which are considered toxic.

For purposes herein, when a phosphor has two or more dopant ions (i.e., those ions following the colon in the above phosphors), it means that the phosphor has at least one (but not necessarily all) of those dopant ions within the material. As understood by those skilled in the art, this notation means that the phosphor can include any or all of those specified ions as dopants in the formulation.

In another embodiment, the light emitting diode devices include at least a violet-emitting LED device capable of emitting electromagnetic radiation at a range from about 380 nanometers to about 440 nanometers and the entities are capable of emitting substantially white light. In a specific embodiment, a (1 −1 0 0) m-plane bulk substrate is provided for the nonpolar violet LED. The substrate has a flat surface, with a root-mean-square (RMS) roughness of about 0.1 nm, a threading dislocation density less than 5×10⁶ cm⁻², and a carrier concentration of about 1×10¹⁷ cm⁻³. Epitaxial layers are deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth is between about 3000 and about 12000. First, a contact layer of n-type (silicon-doped) GaN is deposited on the substrate, with a thickness of about 5 microns and a doping level of about 2×10¹⁸ cm⁻³. Next, an undoped InGaN/GaN multiple quantum well (MQW) is deposited as the active layer. The MQW superlattice has six periods, comprising alternating layers of 16 nm of InGaN and 18 nm of GaN as the barrier layers. Next, a 10 nm undoped AlGaN electron blocking layer is deposited. Finally, a p-type GaN contact layer is deposited, with a thickness of about 160 nm and a hole concentration of about 7×10¹⁷ cm⁻³. Indium tin oxide (ITO) is e-beam evaporated onto the p-type contact layer as the p-type contact and rapid-thermal-annealed. LED mesas, with a size of about 300×300 μm², are formed by photolithography and dry etching. Ti/Al/Ni/Au is e-beam evaporated onto the exposed n-GaN layer to form the n-type contact, Ti/Au is e-beam evaporated onto a portion of the ITO layer to form a contact pad, and the wafer is diced into discrete LED dies. Electrical contacts are formed by conventional wire bonding. Other colored LEDs may also be used or combined according to a specific embodiment. In a similar embodiment, the LED is fabricated on a polar bulk GaN orientation.

In a specific embodiment, the entities comprise a blend of phosphors capable of emitting substantially blue light, substantially green light, and substantially red light. As an example, the blue emitting phosphor can be selected from the group consisting of (Ba,Sr,Ca)₅(PO₄)₃(Cl,F,Br,OH):Eu²⁺, Mn²⁺; Sb³⁺, (Ba,Sr,Ca)MgAl₁₀O₁₇:Eu²⁺, Mn²⁺; (Ba,Sr,Ca)BPO₅:Eu²⁺, Mn²⁺; (Sr,Ca)₁₀(PO₄)₆*nB₂O₃:Eu²⁺; 2SrO*0.84P₂O₅*0.16B₂O₃:Eu²⁺; Sr₂Si₃O₈*2SrCl₂:Eu²⁺; (Ba,Sr,Ca)MgₓP₂O₇:Eu²⁺, Mn²⁺; Sr₄Al₁₄O₂₅:Eu²⁺ (SAE); BaAl₈O₁₃:Eu²⁺; and mixtures thereof. The green phosphor can be selected from the group consisting of (Ba,Sr,Ca)MgAl₁₀O₁₇:Eu²⁺, Mn²⁺ (BAMn); (Ba,Sr,Ca)Al₂O₄:Eu²⁺; (Y,Gd,Lu,Sc,La)BO₃:Ce³⁺,Tb³⁺; Ca₈Mg(SiO₄)₄Cl₂:Eu²⁺,Mn²⁺; (Ba,Sr,Ca)₂SiO₄:Eu²⁺; (Ba,Sr,Ca)₂(Mg,Zn)Si₂O₇:Eu²⁺; (Sr,Ca,Ba)(Al,Ga,In)₂S₄:Eu²⁺; (Y,Gd,Tb,La,Sm,Pr,Lu)₃(Al,Ga)₅O₁₂:Ce³⁺; (Ca,Sr)₈(Mg,Zn)(SiO₄)₄Cl₂:Eu²⁺, Mn²⁺ (CASI); Na₂Gd₂B₂O₇:Ce³⁺, Tb³⁺; (Ba,Sr)₂(Ca,Mg,Zn)B₂O₆:K,Ce,Tb; and mixtures thereof. The red phosphor can be selected from the group consisting of (Gd,Y,Lu,La)₂O₃:Eu³⁺,Bi³⁺; (Gd,Y,Lu,La)₂O₂S:Eu³⁺,Bi³⁺; (Gd,Y,Lu,La)VO₄:Eu³⁺, Bi³⁺; Y₂(O,S)₃:Eu³⁺; Ca₁₋ₓMo_{1-y}Si_{y}O₄: where 0.05≦x≦0.5, 0≦y≦0.1; (Li,Na,K)₅Eu(W,Mo)O₄; (Ca,Sr)S:Eu²⁺; SrY₂S₄:Eu²⁺; CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgₓP₂O₇:Eu²⁺, Mn²⁺; (Y,Lu)₂WO₆:Eu³⁺, Mo⁶⁺; (Ba,Sr,Ca)₃MgₓSi₂O₈:Eu²⁺, Mn²⁺, wherein 1<x≦2; (RE_{1-y}Ce_{y})Mg₂₋ₓLiₓSi₃₋ₓPₓO₁₂, where RE is at least one of Sc, Lu, Gd, Y, and Tb, 0.0001<x<0.1 and 0.001<y<0.1; (Y, Gd, Lu, La)₂,EuₓW_{1-y}Mo_{y}O₆,where 0.5≦x.≦1.0, 0.01≦y≦1.0; (SrCa)₁₋ₓEuₓSi₅N₈, where 0.01≦x≦0.3; SrZnO₂:Sm⁺³; MₘOₙX, wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

It would be recognized that other “energy-converting luminescent materials,” which include phosphors, semiconductors, semiconductor nanoparticles (“quantum dots”), organic luminescent materials, and the like, and combinations of them, can also be used. The energy converting luminescent materials can generally be a wavelength converting material and/or materials.

In one embodiment, the packaged device has a flat carrier configuration and includes an enclosure which includes a flat region that is wavelength selective. The enclosure can be made of a suitable material such as an optically transparent plastic, glass, or other material. The enclosure has a suitable shape 119, which can be annular, circular, egg-shaped, trapezoidal, or other shape. As shown referring to the cup carrier configuration, the packaged device is provided within a terraced or cup carrier. Depending upon the embodiment, the enclosure with suitable shape and material is configured to facilitate and even optimize transmission of electromagnetic radiation reflected from internal regions of the package. The wavelength selective material can be a filter device applied as a coating to a surface region of the enclosure. In a preferred embodiment, the wavelength selective surface is a transparent material such as distributed Bragg Reflector (DBR) stack, a diffraction grating, a particle layer tuned to scatter selective wavelengths, a photonic crystal structure, a nanoparticle layer tuned for plasmon resonance enhancement at certain wavelengths, or a dichroic filter, or other approach.

The wavelength conversion material is usually within about one hundred microns of a thermal sink which is a surface region having thermal conductivity of greater than about 15, 100, 200, or even 300 Watt/m-Kelvin. In a specific embodiment, the wavelength conversion material has an average particle-to-particle distance of about less than about 2 times the average particle size of the wavelength conversion material, but it can be as much as 3 times, 5 times, or even 10 times the average particle size of the wavelength conversion material. Alternatively the wavelength conversion material can be provided as a filter device.

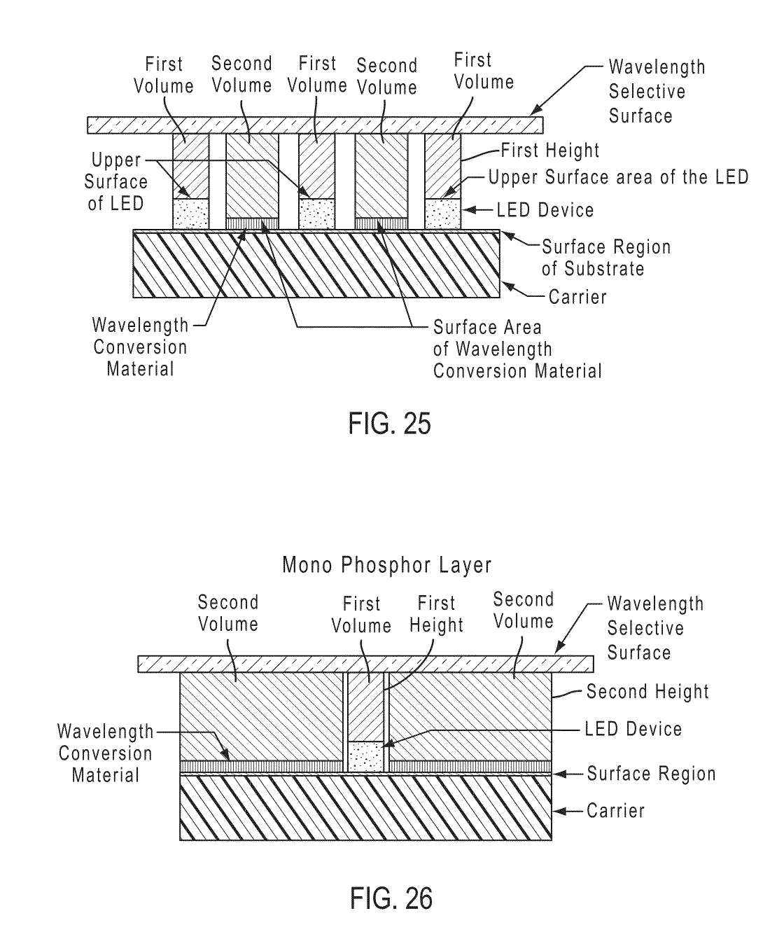

FIGS. 25 to 36 are diagrams of a packaged light emitting devices with reflection mode configurations. The enclosure has an interior region and an exterior region with a volume defined within the interior region. The volume is open and filled with a transparent materials such as silicone, or an inert gas or air to provide an optical path between the LED device or devices and the surface region. In a preferred embodiment, the optical path includes a path from the wavelength selective material to the wavelength conversion material, then back through the wavelength conversion material. In a specific embodiment, the enclosure also has a thickness and fits around a base region of the carrier.

Typically the entities are suspended in a suitable medium. An example of such a medium can be a silicone, glass, spin on glass, plastic, polymer, which is doped, metal, or semiconductor material, including layered materials, and/or composites, among others. Depending upon the embodiment, the medium including polymers begins as a fluidic state, which fills an interior region of the enclosure, and can fill and seal the LED device or devices. The medium is then cured and achieves a substantially stable state. The medium is preferably optically transparent, but can also be selectively transparent. In addition, the medium, once cured, is usually substantially inert. In a preferred embodiment, the medium has a low absorption capability to allow a substantial portion of the electromagnetic radiation generated by the LED device to traverse through the medium and be provided through the enclosure at desired wavelengths. In other embodiments, the medium can be doped or treated to selectively filter, disperse, or influence the selected wavelengths of light. As an example, the medium can be treated with metals, metal oxides, dielectrics, or semiconductor materials, and/or combinations of these materials.

The LED device can be configured in a variety of packages such as cylindrical, surface mount, power, lamp, flip-chip, star, array, strip, or geometries that rely on lenses (silicone, glass) or sub-mounts (ceramic, silicon, metal, composite). Alternatively, the package can be any variations of these packages.

In other embodiments, the packaged device can include other types of optical and/or electronic devices such as an OLED, a laser, a nanoparticle optical device, etc. If desired, the optical device can include an integrated circuit, a sensor, a micro-machined electronic mechanical system, or other device. The packaged device can be coupled to a rectifier to provide a power supply. The rectifier can be coupled to a suitable base, such as an Edison screw such as E27 or E14, bi-pin base such as MR16 or GU5.3, or a bayonet mount such as GU10. In other embodiments, the rectifier can be spatially separated from the packaged device.

The ultimate pixel resolution limit on a screen made of phosphors particles is the phosphor particle sizes themselves. By producing a phosphor layer whose thickness is on the scale of the particle diameter, effective ‘natural pixelation’ is produced, wherein each grain becomes a pixel. That is, the colored pixel is defined by a single phosphor particle. The inventors have determined that a properly designed recycling cavity (e.g., selective reflective member) can enable extended absorption path lengths thus minimizing required phosphor quantities to produce proper final colors, even to such a phosphor ‘mono-layer’ or sub-mono-layer. Single or multi particle screens of this type would improve thermal performance, package optical efficiency, and overall performance of the LED device. Numerous extensions of the concept can be applied to mixed, remote, layered plate-like configurations of phosphors.

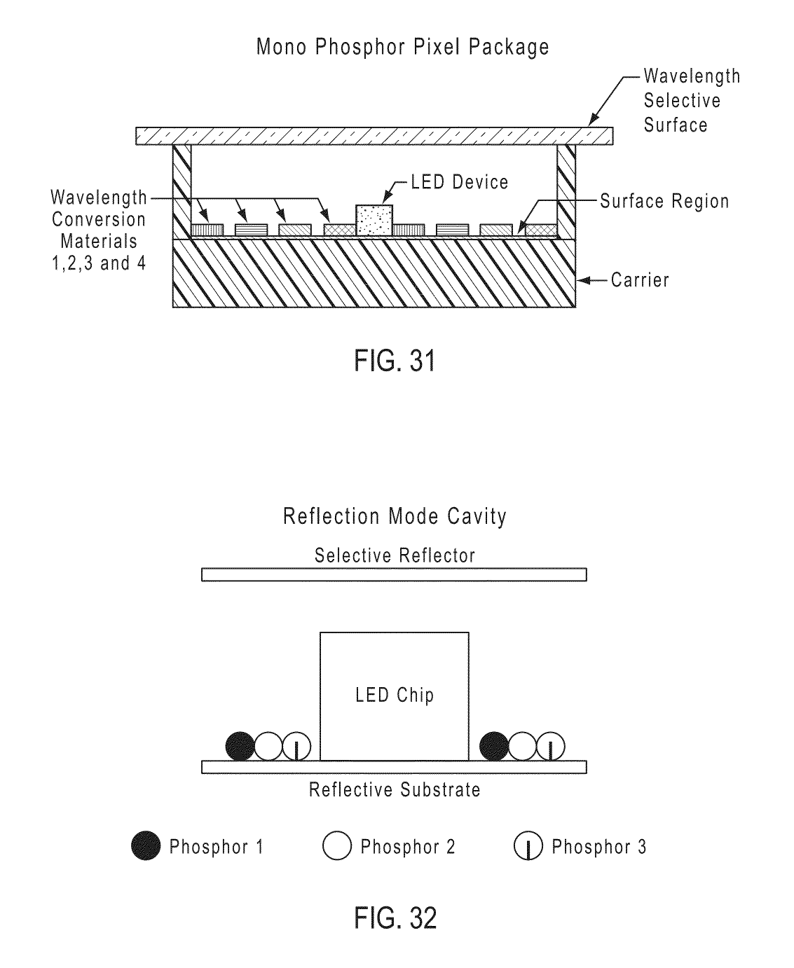

FIG. 31 shows an embodiment of the invention employing this concept. In this case the overall thickness of the reflection mode phosphor layer is on the order of the average grain height. The selected packing density of the phosphor can even allow gaps between grains, and achieve high conversion efficiency provided the surface upon which the grains lie is sufficiently reflective. Of course, multiple phosphors can be included in the reflection mode layer, for example red, green, and/or blue emitting phosphors for white-emitting LEDs. Benefits include optimum thermal configuration for particles (direct or near direct attach to substrate), minimizing crosstalk between phosphor particles thus minimizing cross absorption events, minimum use of expensive phosphor materials, minimum processing steps to produce an n-color screen, and minimization of far-field color separation.

Methods to apply the thin phosphor layer include, but are not limited to, spray coating/electrostatic powder coating, ultrasonic spray coating with baffle electrode in the path of the powders for charging the powders, single layer particle self-assembly, dip pen lithography, mono layer electrophoretic deposition, sedimentation, phototacky application with dry dusting, electrostatic pickup with tacky attach, dip coating, etc.

Prior art (for example, Krames et al. in U.S. Pat. No. 7,026,66) shows a reduction in phosphor conversion efficiency for more than 30% direct emission from the primary LEDs. Reflection mode devices such as described here, however, improve in efficiency as the direct emission from the LEDs to the reflector is increased, since phosphor particles are not present to back-scatter light into the LED devices, which can then be lost. This is a central advantage of the reflection mode concept.

Johnson teaches (J. Opt. Soc. Am 42, 978, 1952) in the phosphor handbook (Shionoya and Yen, 16, 787, 1999) that there exists a relationship between fluorescent brightness and number of phosphor particle layers. This is shown to be about 5 particle layers based on halophosphate powder modeling. Brightness steadily drifts down as the number of particle layers increases to 10 layers (30% loss from 4 to 10 layers). Given typical particle sizes in LED based applications as 15 μm to 20 μm, and an estimated peak fluorescence at 5 layers, it is desirable to have the maximum thickness of the wavelength conversion material at less than or equal to ˜100 μm.

The reflection mode geometry, which is partly defined by the requirement that 30% of the emitted chip light must first strike the wavelength selective surface prior to striking the phosphor conversion material, eliminates highly scattering media from around the vicinity of the emitting chips and in the volume between the chips and the wavelength selective surface. This reduces backscatter losses within the chip as well as package level scattering losses, resulting in a more efficient optical design. In addition, the generation of wavelength converted light occurs predominately at the top surface of the wavelength conversion material, allowing this created light the least impeding optical path to exit from the package. By ensuring that the wavelength conversion material is placed on the surface region of the mounting member, the wavelength conversion material is provided with the optimum thermal path for heat dissipation, allowing the wavelength conversion material to operate at reduced temperature and higher conversion efficiency than designs where the wavelength conversion material does not have an adequate thermal path to operate at the lowest possible temperatures. By limiting the thickness of the wavelength conversion material layer to 100 μm or less, the thermal path is not compromised by the thickness of the wavelength conversion material itself.

In tests, the inventors found that very thin layers of phosphors are all that are required if the recycling effect is strong enough. In fact, even less than a “monolayer” of phosphor material can result in high conversion. This gives the benefits of a) reduced amount of phosphor material required, b) provision of thinner layer which is better for heat sinking, and c) a ‘natural pixelation’ resulting in less cascading down-conversion events (i.e., where violet pumps blue pumps green pumps red).

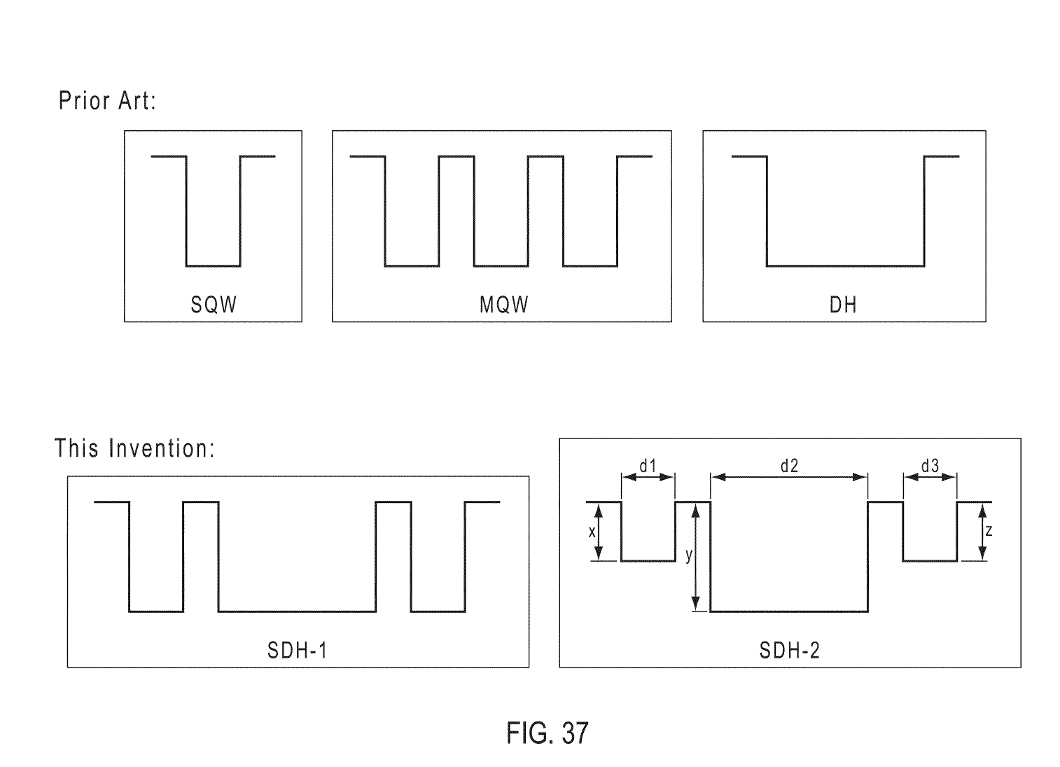

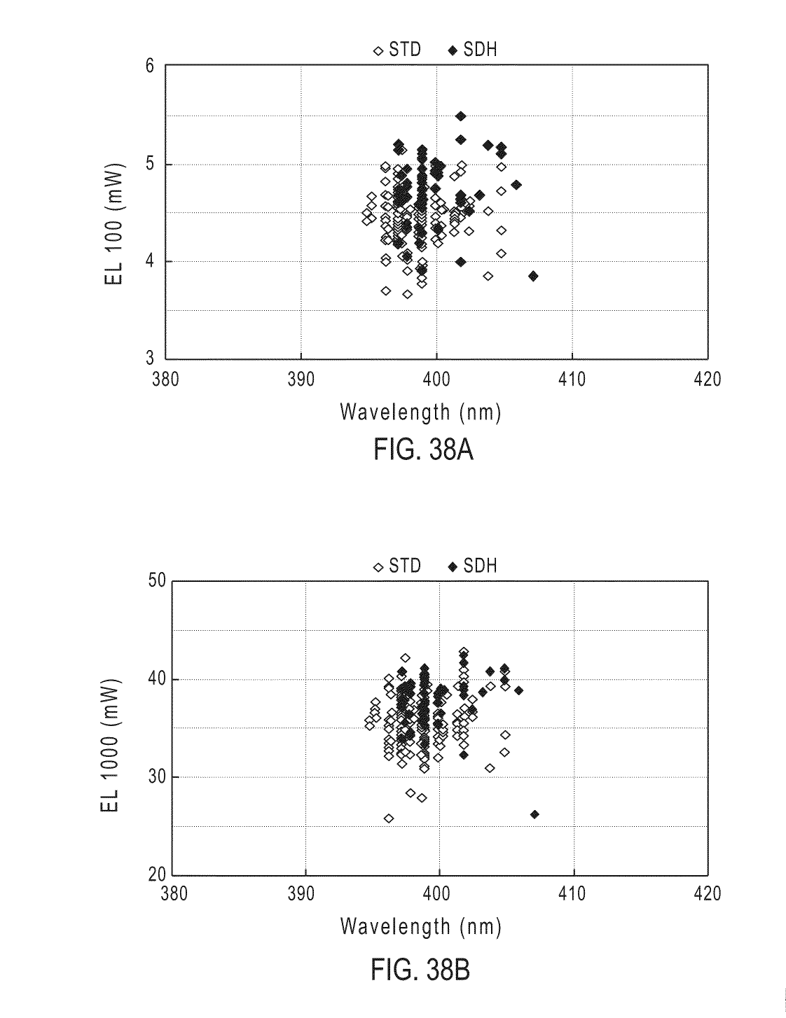

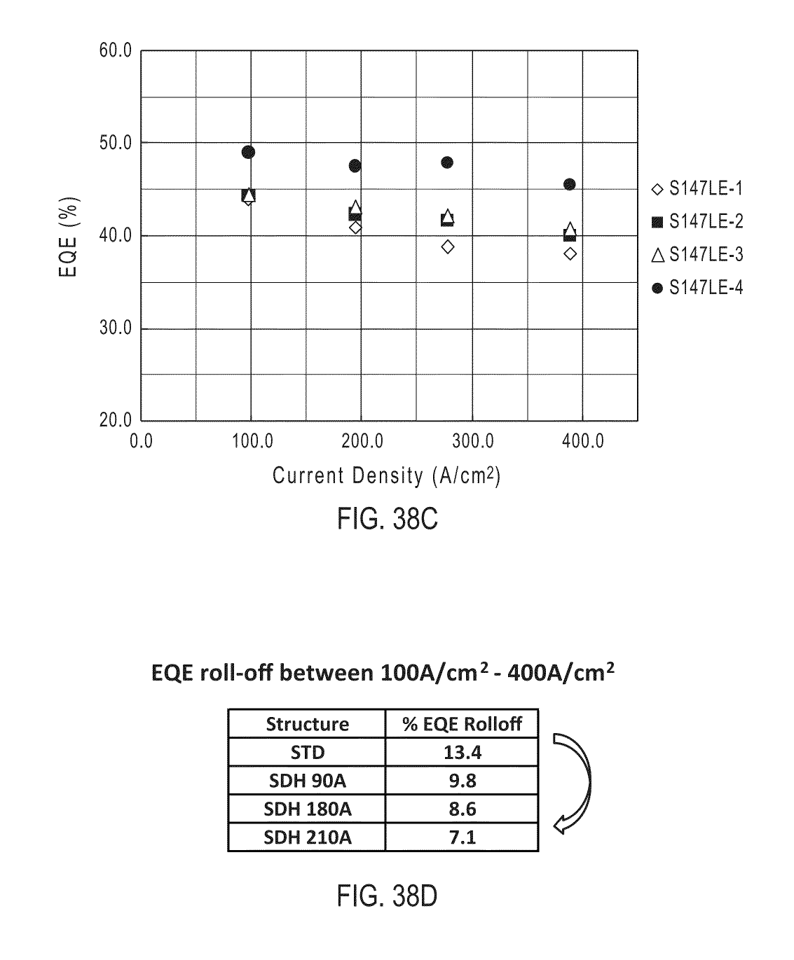

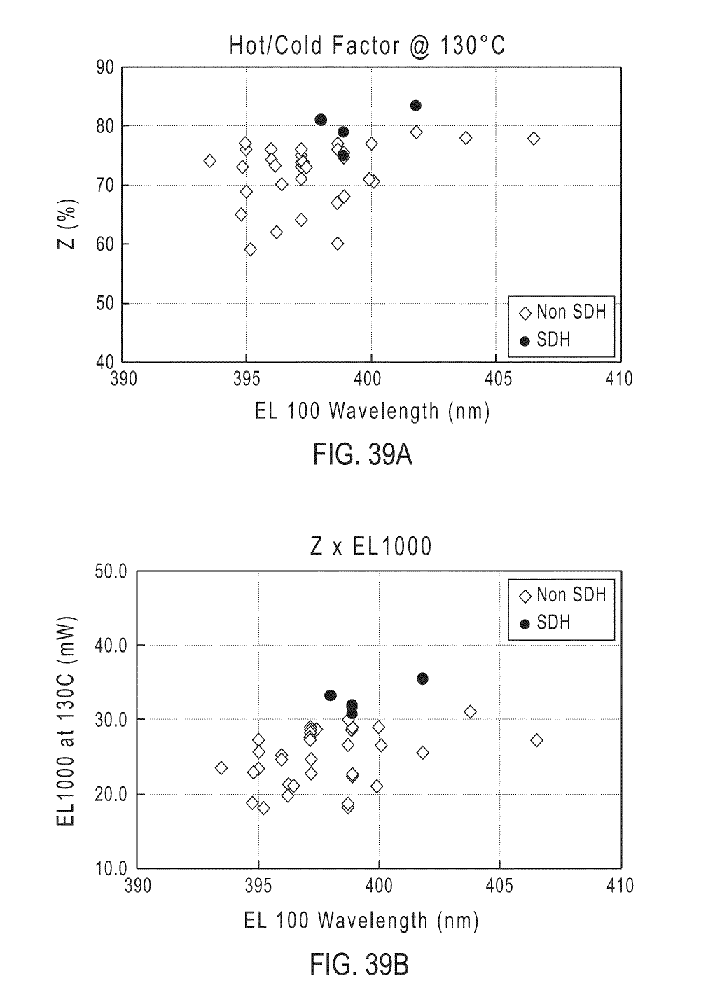

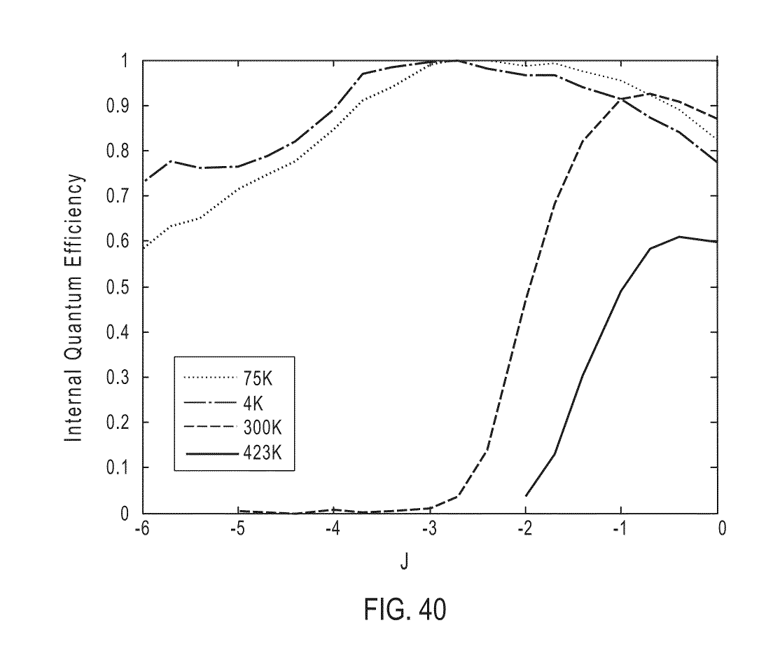

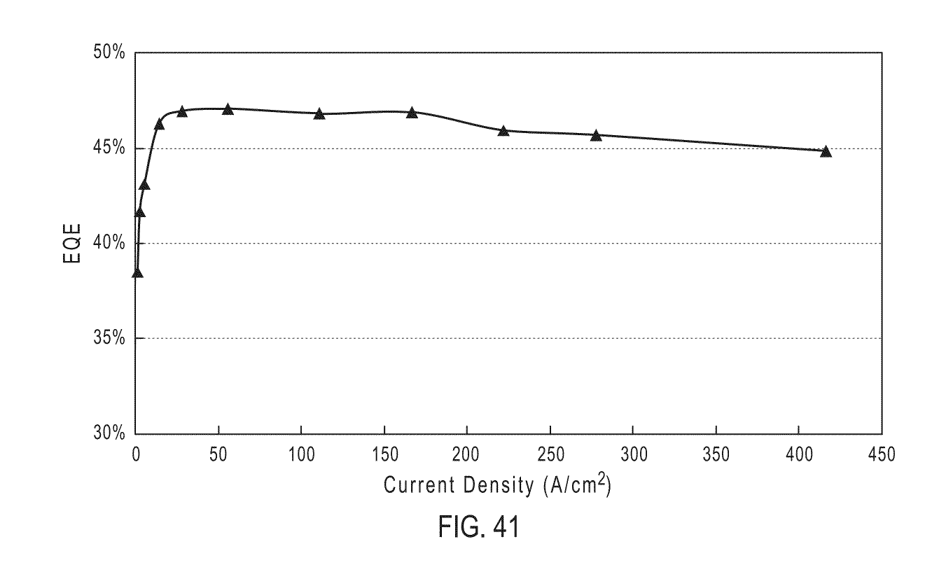

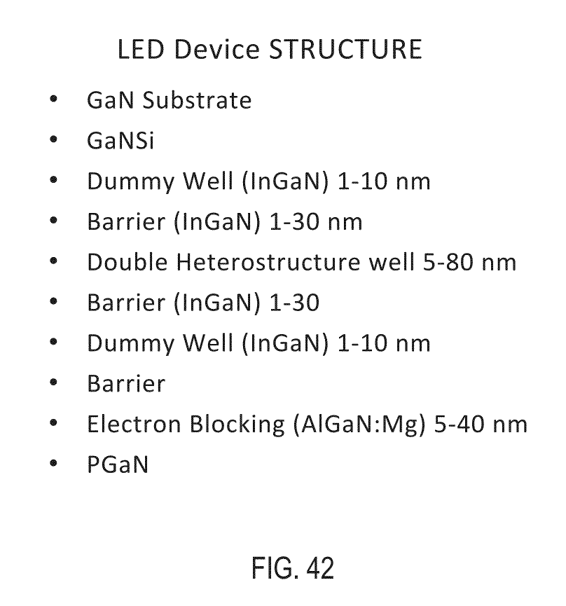

In certain embodiments, LED devices provided by the present disclosure include those shown in FIGS. 37 to 42.

Growth on foreign substrates often requires low temperature or high temperature nucleation layers at the substrate interface, techniques such as lateral epitaxial overgrowth to mitigate the misfit defects formed at the GaN/substrate interface, a thick buffer layer usually consisting of n-type GaN, but could be others such as InₓAl_{y}Ga_{1-x-y}N, grown between the substrate and light emitting active layers to reduce adverse effects of the misfit defects, InGaN/GaN or AlGaN/GaN or AlInGaN/AlInGaN superlattices placed between the substrate and light emitting active layers to improve the radiative efficiency through strain mitigation, defect mitigation, or some other mechanism, InGaN or AlGaN buffer layers placed between the substrate and light emitting active layers to improve the radiative efficiency through strain mitigation, defect mitigation, or some other mechanism, and thicker p-type GaN layers to mitigate electrostatic discharge (ESD) and reduce leakage current. With the inclusion of all of these layers, conventional LED growth can take from 4 hours to 10 hours.

By growing LEDs on bulk GaN substrates the low temperature nucleation layer can be eliminated, for example. Defect mitigation techniques such as lateral epitaxial overgrowth are not necessary since there are no misfit dislocation. There is often no need to employ alloyed superlattices or alloy layers between the substrate and the active region to improve radiative efficiency. Furthermore, since the many various growth layers required in conventional LEDs grown on foreign substrates often necessitate different growth temperatures the reduced number of growth layers in the LED structure will also require less temperature ramping in the growth recipe. As the total growth time is reduced, the fraction of temperature ramp time within the total cycle time becomes more significant. Therefore the reduced ramping required in this scheme is critical to high growth throughput.

In a specific embodiment, the present method provides a bulk gallium and nitrogen containing substrate. In a specific embodiment, the gallium nitride substrate member is a bulk GaN substrate characterized by having a semipolar or non-polar crystalline surface region, but can be others. In a specific embodiment, the bulk nitride GaN substrate comprises nitrogen and has a surface dislocation density below 10⁵ cm⁻². The nitride crystal or wafer may comprise AlₓIn_{y}Ga_{1-x-y}N, where 0≦x, y, x+y≦1. In one specific embodiment, the nitride crystal comprises GaN, but can be others. In one or more embodiments, the GaN substrate has threading dislocations, at a concentration between about 10⁵ cm⁻² and about 10⁸ cm⁻², in a direction that is substantially orthogonal or oblique with respect to the surface. As a consequence of the orthogonal or oblique orientation of the dislocations, the surface dislocation density is below about 10⁵ cm⁻². In a preferred embodiment, the present method may include a gallium and nitrogen containing substrate configured with any orientation, e.g., c-plane, a-plane, m-plane. In a specific embodiment, the substrate is preferably (Al,Ga,In)N based. The substrate has a threading dislocation (TD) density <1E8 cm⁻², a stacking fault (SF) density <5E3 cm⁻¹, and may be doped with silicon and/or oxygen with a concentration of >1E17 cm⁻³. Of course, there can be other variations, modifications, and alternatives.

As shown, the method forms an n-type material overlying the surface of the gallium and nitrogen containing substrate. In a specific embodiment, the n-type material is formed epitaxially and has a thickness of less than 2 microns, or less than 1 micron, or less than 0.5 micron, or less than 0.2 micron, or can be others. In a specific embodiment, the n-type material is (Al,Ga,In)N based. Growth occurs using a temperature of less than about 1,200 Degrees Celsius or less than about 1,000 Degrees Celsius, but often is greater than 950 Degrees Celsius. In a preferred embodiment, the n-type material is unintentionally doped (UID) or doped using a silicon species (e.g., Si) or oxygen species (e.g., O₂). In a specific embodiment, the dopant may be derived from silane, disilane, oxygen, or the like. In a specific embodiment, the n-type material serves as a contact region of the n-type (silicon-doped) GaN and is characterized by a thickness of about 5 microns and a doping level of about 2×10¹⁸ cm⁻³. In a preferred embodiment, gallium and nitrogen containing epitaxial material is deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth is between about 3,000 and about 12,000. Of course, there can be other variations, modifications, and alternatives.

In a preferred embodiment, the method forms an active region overlying the n-type contact region. The active region includes at least a double heterostructure well region with at least one dummy well on each side of the double heterostructure well region. Optionally, the active region may also include a barrier region or barrier regions.

In a specific embodiment, an AlGaN electron blocking region is deposited. In a preferred embodiment, a p-type GaN contact region is deposited.

In a specific embodiment, Indium tin oxide (ITO) is e-beam evaporated onto the p-type contact layer as the p-type contact and rapid-thermal-annealed. LED mesas, with a size of about 300×300 μm², are formed by photolithography and dry etching using a chlorine-based inductively-coupled plasma (ICP) technique. Ti/Al/Ni/Au is e-beam evaporated onto the exposed n-GaN layer to form the n-type contact, Ti/Au is e-beam evaporated onto a portion of the ITO layer to form a p-contact pad, and the wafer is diced into discrete LED dies. Electrical contacts are formed by conventional wire bonding. Of course, there can be other variations, modifications, and alternatives.

In a preferred embodiment, the present method provides a smooth resulting epitaxial material. Using for example, n-type gallium and nitrogen containing material, surface roughness is characterized by about 1 nm RMS and less for a five micron by five micron spatial area. In a specific embodiment using, for example, p-type gallium and nitrogen containing material, surface roughness is characterized by about 1 nm RMS and less for a five micron by five micron spatial area. Of course, there can be other variations, modifications, and alternatives.

In a specific embodiment, the nitride crystal comprises nitrogen and has a surface dislocation density below 10⁵ cm⁻². The nitride crystal or wafer may comprise AlₓIn_{y}Ga_{1-x-y}N, where 0≦x, y, x+y≦1. In one specific embodiment, the nitride crystal comprises GaN. In a preferred embodiment, the nitride crystal is substantially free of low-angle grain boundaries, or tilt boundaries, over a length scale of at least 3 millimeters. The nitride crystal may also include a release layer with an optical absorption coefficient greater than 1000 cm⁻¹ at least one wavelength where the base crystal underlying the release layer is substantially transparent, with an optical absorption coefficient less than 50 cm⁻¹, and may further comprise a high quality epitaxial layer, which also has a surface dislocation density below 10⁵ cm⁻². The release layer may be etched under conditions where the nitride base crystal and the high quality epitaxial layer are not. Of course, there can be other variations, modifications, and alternatives.

In a specific embodiment, the substrate may have a large-surface orientation within ten degrees, within five degrees, within two degrees, within one degree, within 0.5 degree, or within 0.2 degree of (0 0 0 1), (0 0 0 −1), {1 −1 0 0}, {1 1 −2 0}, {1 −1 0±1}, {1 −1 0±2}, {1 −1 0±3}, or {1 1 −2±2}. The substrate may have a dislocation density below 10⁴ cm⁻², below 10³ cm⁻², or below 10² cm⁻². The nitride base crystal or wafer may have an optical absorption coefficient below 100 cm⁻¹, below 50 cm⁻¹ or below 5 cm⁻¹ at wavelengths between about 465 nm and about 700 nm. The nitride base crystal may have an optical absorption coefficient below 100 cm⁻¹, below 50 cm⁻¹ or below 5 cm⁻¹ at wavelengths between about 700 nm and about 3,077 nm and at wavelengths between about 3,333 nm and about 6,667 nm. Of course, there can be other variations, modifications, and alternatives.

In certain embodiments, an LED device comprises a GaN substrate, a GaNSi layer overlying the GaN substrate, a 1 nm to 10 nm thick InGaN dummy well overlying the GaNSi layer, a 1 nm to 30 nm thick InGaN barrier layer overlying a the InGaN dummy well, a 5 nm to 80 nm thick double heterostructure layer overlying the InGaN barrier layer, a 1 nm to 30 nm thick InGaN barrier layer overlying the double heterostructure layer, a 1 nm to 10 nm thick InGaN dummy well layer overlying the InGaN barrier layer, a barrier layer overlying the dummy well layer, a 5 nm to 40 nm thick AlGaN:Mg electron blocking layer overlying the barrier layer, and a p-GaN layer overlying the electron blocking layer.

In certain embodiments, an optical device such as an LED device comprises: a bulk gallium and nitrogen containing substrate having a surface region; a n-type gallium and nitrogen containing epitaxial material formed overlying the surface region; an active region comprising a double heterostructure well region, and at least one dummy well configured on each side of the double heterostructure well region, each of the at least one dummy wells having a width of about ten percent to about ninety percent of a width of the double heterostructure well region; a p-type gallium and nitrogen containing epitaxial material formed overlying the active region; and a contact region formed overlying the p-type gallium and nitrogen containing epitaxial material.

In certain embodiments of an optical device, the surface region is configured in a c-plane, m-plane, or a-plane orientation, which may be off-cuts, or any semipolar plane.

In certain embodiments of an optical device, the surface region is configured in c-plane orientation; and each of the at least one dummy wells has a width of about twenty percent to about thirty percent of a width of the double heterostructure well region.

In certain embodiments of an optical device, the surface region is configured in m-plane orientation; and each of the at least one dummy wells has a width of about twenty percent to about ninety percent of a width of the double heterostructure well region.

In certain embodiments of an optical device, the double heterostructure well region has a thickness ranging from 90 Angstroms to 50 Angstroms, or from 200 Angstroms to 400 Angstroms.

In certain embodiments of an optical device, each of the at least one dummy wells has a thickness ranging from 30 Angstroms to eighty Angstroms.

In certain embodiments of an optical device, the double heterostructure well region is positioned between at least two GaN layers, at least two InₓGa₁₋ₓN, Al_{y}Ga_{1-y}N layers, at least two InₓAl_{y}Ga_{(1-x-y)}N, layers, or between two layers comprising GaN, InₓGa₁₋ₓN, Al_{y}Ga_{1-y}N, or InₓAl_{y}Ga_{(1-x-y)}N.

In certain embodiments of an optical device, the double heterostructure well region is configured to emit a substantial portion of electromagnetic radiation generated from the active region; and each of the at least one dummy wells is configured to facilitate the generation of the electromagnetic radiation, while substantially not generating electromagnetic radiation in each of the at least one dummy wells.

In certain embodiments, an optical device further comprises multiple dummy well regions configured on either side of the double heterostructure well region.

In certain embodiments of an optical device, the double heterostructure well region comprises In_{z}Ga_{1-z}N.

In certain embodiments, an optical device comprises an n-type InGaN/GaN superlattice region wherein the double heterostructure well region is formed overlying the n-type InGaN/GaN superlattice region.

Methods for manufacturing optical devices such as LED devices provided by the present disclosure are also disclosed. In certain embodiments, methods for manufacturing an optical device comprise: providing a bulk gallium and nitrogen containing substrate having a surface region; forming a n-type gallium and nitrogen containing epitaxial material overlying the surface region; forming an active region comprising a double heterostructure well region, and at least one dummy well configured on each side of the double heterostructure well region, each of the at least one dummy wells having a width of about ten percent to about ninety percent of a width of the double heterostructure well region; forming a p-type gallium and nitrogen containing epitaxial material overlying the active region; and forming a contact region overlying the p-type gallium and nitrogen containing epitaxial material.

In certain methods, the surface region is configured in a c-plane, m-plane, or a-plane orientation, which may be off-cuts, or semipolar orientation.

In certain methods, the surface region is configured in c-plane orientation; and each of the dummy wells having a width of about twenty percent to about thirty percent of a width of the double heterostructure well region.

In certain methods, the surface region is configured in m-plane orientation; and each of the at least one dummy wells has a width of about twenty percent to about ninety percent of a width of the double heterostructure well region.

In certain methods, the double heterostructure well region has a thickness ranging from 90 Angstroms to 500 Angstroms, or from 200 Angstroms to 400 Angstroms.

In certain methods, each of the at least one dummy wells has a thickness ranging from 30 Angstroms to 80 Angstroms.

In certain methods, the double heterostructure well region is positioned between at least two GaN layers, at least two InₓGa₁₋ₓN, Al_{y}Ga_{1-y}N layers, at least two InₓAl_{y}Ga_{(1-x-y)}N, layers, or between two layers comprising GaN, InₓGa₁₋ₓ,N, Al_{y}Ga_{1-y}N, or InₓAl_{y}Ga_{(1-x-y)}N.

In certain methods, the double heterostructure well region is configured to emit a substantial portion of electromagnetic radiation generated from the active region; and each of the at least one dummy wells is configured to facilitate the generation of the electromagnetic radiation, while substantially not generating electromagnetic radiation in each of the dummy cell regions.

In certain methods, further comprising multiple dummy wells configured on either side of the double heterostructure well region.

In certain methods, the double heterostructure well region comprises In_{z}Ga_{1-z}N.

In certain methods, comprise an n-type InGaN/GaN superlattice region, wherein the double heterostructure well region overlies the n-type InGaN/GaN superlattice region.

The following examples describe in detail examples of constituent elements of the herein-disclosed embodiments. It will be apparent to those skilled in the art that many modifications, both to materials and methods, may be practiced without departing from the scope of the disclosure.

### Embodiment 1

An LED lamp comprising an LED device emitting more than 500 lm, and for which more than 2% of the power in the SPD is emitted within the range of about 390 nm to about 430 nm. A lamp in this (and other) embodiments can be obtained by these approaches: (i) use violet pump LEDs only, (ii) add violet LEDs to a blue-pump based system, or (iii) or a combination of blue and violet pump LEDs.

### Embodiment 2

The lamp of embodiment 1, wherein more than 5% of power in the SPD is emitted within the range about 390 nm to about 430 nm.

### Embodiment 3

The lamp of embodiment 1, wherein less than 1% of power in the SPD is emitted below 400 nm.

### Embodiment 4

The lamp of embodiment 1, wherein the beam angle is narrower than 15° and the center-beam candle power is greater than 15000cd.

### Embodiment 5

The lamp of embodiment 1, emitting at least 1500 lm.

### Embodiment 6

The lamp of embodiment 1, further comprising an MR16 form factor.

### Embodiment 7

The lamp of embodiment 1, wherein an output facet of the lamp has a diameter of about 121 mm.

### Embodiment 8

The lamp of embodiment 1, further comprising a PAR30 lamp form factor.

### Embodiment 9

The lamp of embodiment 1, wherein at least part of power in the SPD is provided by at least one violet-emitting LED.

### Embodiment 10

The lamp of embodiment 9, wherein the at least one violet-emitting LED emits more than 200 W/cm² at a current density of 200 A/cm² at a junction temperature of 100° C. or greater.

### Embodiment 11

The lamp of embodiment 9, wherein the at least one violet-emitting LED pumps at least a blue or cyan phosphor.

### Embodiment 12

The lamp of embodiment 9, wherein the at least one violet-emitting LED pumps more than one blue/cyan phosphors.

### Embodiment 13

The lamp of embodiment 9: further comprising at least one LED emitting at wavelengths other than the violet-emitting LED The lamp of embodiment 1, wherein the SWSD for a source with a CCT in the range 2500K-7000K is less than 35%.

### Embodiment 14

The lamp of embodiment 1, wherein the SWSD for a source with a CCT in the range 5000K-7000K is less than 35%.

### Embodiment 15

The lamp of embodiment 1, wherein the violet leak is lower than 10%.

### Embodiment 16

The lamp of embodiment 1, wherein the CIE whiteness of a typical white paper is improved by at least 5 points, over a similar lamp which would have no significant SPD component in the range about 390 nm to about 430 nm.

### Embodiment 17

The lamp of embodiment 1, wherein the violet leak is configured to achieve a particular CIE whiteness value.

### Embodiment 18

The lamp of embodiment 1, wherein the violet leak is such that a CIE whiteness of a high-whiteness reference sample illuminated by the lamp is within minus 20 points and plus 40 points of a CIE whiteness of the same sample under illumination by a CIE reference illuminant of same CCT (respectively a blackbody radiator if CCT<5000K or a D illuminant if CCT>5000K).

### Embodiment 19

The lamp of embodiment 1, wherein the violet leak is such that a CCT-corrected Whiteness of a high-whiteness reference object illuminated by the lamp is within minus 20 points and plus 40 points of a CCT-corrected Whiteness of the same object under illumination by a CIE reference illuminant of same CCT (respectively a blackbody radiator if CCT<5000K or a D illuminant if CCT>5000K).

### Embodiment 20

The lamp of embodiment 1, wherein the violet leak is such that a (u′v′) chromaticity shift with respect to the source's white point of a high-whiteness reference sample illuminated by the lamp, when compared to a chromaticity shift of the same sample under illumination by a CIE reference illuminant of same CCT (respectively a blackbody radiator if CCT<5000K or a D illuminant if CCT>5000K) is (i) substantially in the same direction; and (ii) at least of a similar magnitude.

### Embodiment 21

The lamp of embodiment 1, wherein part of the blue light is provided by LEDs

### Embodiment 22

The lamp of embodiment 1, wherein a beam angle is narrower than 25° and a center-beam candle power is higher than 2200cd.

### Embodiment 23

The lamp of embodiment 1, wherein the lamp is an MR-16 form factor.

### Embodiment 24

The lamp of embodiment 1, wherein a CRI for a source with a CCT in the range about 2500K to about 7000K is more than 90.

### Embodiment 25

The lamp of embodiment 1, wherein a CRI for a source with a CCT in the range about 5000K to about 7000K is more than 90.

### Embodiment 26

The lamp of embodiment 1, wherein a R9 is more than 80.

### Embodiment 27

The lamp of embodiment 1, wherein a Large-sample set CRI is more than 80.

### Embodiment 28

An LED-based lamp emitting more than 500 lm, comprising one or more LED source die having a base area of less than 40 mm².

### Embodiment 29

The lamp of embodiment 29, wherein more than 2% of the power in the SPD is emitted within the range about 390 nm to about 430 nm.

### Embodiment 30

The lamp of embodiment 29, wherein the lamp is an MR-16 form factor.

### Embodiment 31

The lamp of embodiment 29, wherein the diameter of the optical lens is less than 40 mm.

### Embodiment 32

The lamp of embodiment 29, wherein the partial shadow angular width is less than 1°.

### Embodiment 33

The lamp of embodiment 29, wherein the chromaticity variation Duv is less than 8, for two points in the partial shadow region.

### Embodiment 34

The lamp of embodiment 29, wherein the chromaticity variation Duv of the beam is less than 8 between the center of the emitted beam, and a point with 10% intensity.

### Embodiment 35

A light source comprising LEDs, for which at least 2% of the SPD is in the range about 390 to about 430 nm, and such that a CIE whiteness of a high-whiteness reference sample illuminated by the light source is within minus 20 points and plus 40 points of a CIE whiteness of the same sample under illumination by a CIE reference illuminant of same CCT (respectively a blackbody radiator if CCT<5000K or a D illuminant if CCT>5000K).

### Embodiment 36

The light source of embodiment 36, wherein a CIE whiteness of a high-whiteness reference sample illuminated by the light source is at most 200% of a CIE whiteness of the same sample under illumination by a CIE reference illuminant of same CCT (respectively a blackbody radiator if CCT<5000K or a D illuminant if CCT>5000K).

### Embodiment 37

A light source comprising LEDs, for which at least 2% of the SPD is in the range 390-430 nm, and such that a CIE Whiteness of a high-whiteness reference sample illuminated by the light source is within minus 20 points to plus 40 points of a CIE Whiteness of the same sample under illumination by a CIE reference illuminant of same CCT (respectively a blackbody radiator if CCT<5000K or a D illuminant if CCT>5000K).

### Embodiment 38

A light source comprising LEDs, for which at least 2% of the SPD is in the range 390 nm to 430 nm, and such that a CIE Whiteness of a high-whiteness reference sample illuminated by the light source is within minus 20 points to plus 40 points of a CIE Whiteness of the same sample under illumination by a ceramic metal halide illuminant of same CCT.

### Embodiment 39

The light source of embodiment 38, wherein a CCT-corrected Whiteness of a high-whiteness reference sample illuminated by the light source is at most 200% of a CCT-corrected Whiteness of the same sample under illumination by a CIE reference illuminant of same CCT (respectively a blackbody radiator if CCT<5000K or a D illuminant if CCT>5000K).

### Embodiment 40

A light source comprising LEDs, for which at least 2% of the SPD is in the range 390-430 nm, and such that a chromaticity of a high-whiteness reference sample illuminated by the source is at least two Duv points and at most twelve Duv points away from a chromaticity of the source's white point, and substantially toward the blue direction.

### Embodiment 41

A light source comprising LEDs, for which at least 2% of the SPD is in the range 390 nm to 430 nm, and such that a chromaticity of a commercial white paper with a CIE Whiteness of at least 130, illuminated by the source, is at least two Duv points away from a chromaticity of the source's white point, and toward the blue direction.

### Embodiment 42

A method comprising: selecting an object containing OBAs; measuring an optical excitation of the OBAs under a light source which contains no LEDs; and producing a light source comprising LEDs, for which at least 2% of the SPD is in the range 390-430 nm, and such that an optical excitation of the OBAs under the LED light source is at least 50% of the optical excitation of OBAs under the light source which contains no LEDs.

### Embodiment 43

The method of embodiment 42, wherein the light source which contains no LEDs is either a halogen or ceramic metal halide source.

### Embodiment 44

A method comprising: selecting an object containing OBAs; measuring a chromaticity of the object under a light source which contains no LEDs, called reference chromaticity; and producing a light source comprising LEDs, for which at least 2% of the SPD is in the range 390 nm to 430 nm, and such that a chromaticity of the object under the LED light source is within 5 Duv points of the reference chromaticity.

### Embodiment 45

The method of embodiment 44, wherein the light source which contains no LEDs is either a halogen or ceramic metal halide (CMH) source.

### Embodiment 46

A light source comprising LEDs, for which at least 2% of the SPD is in the range 390-430 nm, and such that a using CCT-corrected Whiteness of a high-whiteness reference sample illuminated by the light source is within minus 20 points to plus 40 points of a CCT-corrected Whiteness of the same sample under illumination by a CIE reference illuminant of same CCT-corrected Whiteness value.

### Example Lamp Embodiment

The following example describes a lamp embodiment of the disclosure. The embodiment is an MR-16 lamp. It contains an LED source comprising violet pump LEDs pumping three phosphors—a red, a green and a blue phosphor. The lamp emits more than 500 lm and has a CCT in the range 2700K to 3000K. The diameter of the LED source is 6 mm and the diameter of the optical lens is 30 mm. The lamp has a beam angle of 25 degrees and a center-beam candle power of at least 2200 candelas.

Finally, it should be noted that there are alternative ways of implementing the embodiments disclosed herein. Accordingly, the present embodiments are to be considered as illustrative and not restrictive, and the claims are not to be limited to the details given herein, but may be modified within the scope and equivalents thereof.

What is claimed is:

1. An LED lamp comprising an LED device, wherein the LED lamp is characterized by a luminous flux of more than 500 lm, and a spectral power distribution (SPD) in which more than 2% of the power is emitted within a wavelength range from about 390 nm to about 430 nm.

2. The lamp of claim 1, wherein the luminous flux is at least 1500 lm.

3. The lamp of claim 1, wherein the lamp comprises an MR16 form factor.

4. The lamp of claim 1, wherein the lamp comprises a PAR30 lamp form factor.

5. The lamp of claim 1, wherein the LED device comprises at least one violet-emitting LED.

6. The lamp of claim 5, wherein the at least one violet-emitting LED is configured to emit more than 200W/cm² at a current density of 200 A/cm² at a junction temperature of 100° C. or greater.

7. The lamp of claim 5, wherein the at least one violet-emitting LED pumps at least a blue phosphor or at least one cyan phosphor.

8. The lamp of claim 5, wherein the LED device comprises at least one LED configured to emit at a wavelength other than a wavelength emitted by the at least one violet-emitting LED.

9. The lamp of claim 1, wherein a short wavelength SPD discrepancy (SWSD) for a source with a correlated color temperature (CCT) in a range 2500K to 7000K is less than 35%.

10. The lamp of claim 1, wherein a violet leak of the light source is configured to achieve a particular CIE whiteness value.

11. The lamp of claim 10, wherein the violet leak is such that a CIE whiteness of a high-whiteness reference sample illuminated by the lamp is within minus 20 points and plus 40 points of a CIE whiteness of the same sample under illumination by a CIE reference illuminant of same CCT (respectively a blackbody radiator if CCT<5000K or a D illuminant if CCT>5000K).

12. The lamp of claim 10, wherein the violet leak is such that a CCT-corrected Whiteness of a high-whiteness reference object illuminated by the lamp is within minus 20 points and plus 40 points of a CCT-corrected Whiteness of an identical object under illumination by a CIE reference illuminant of a same CCT (respectively a blackbody radiator if CCT<5000K or a D illuminant if CCT>5000K).

13. The lamp of claim 1, wherein the LED device comprises at least one blue-emitting LED and at least a portion of blue light is provided by LEDs.

14. The lamp of claim 1, wherein light emitted by the lamp is characterized by a beam angle narrower than 25° and a center-beam candle power higher than 2200cd.

15. The lamp of claim 1, wherein a color rendering index (CRI) for a source with a CCT in the range about 2500K to about 7000K is more than 90.

16. The lamp of claim 1, wherein a R9 is more than 80.

17. The lamp of claim 1, wherein a Large-sampleset CRI is more than 80.

18. An LED-based lamp characterized by a luminous flux of more than 500 lm, wherein the lamp comprises one or more LED source die having a base area of less than 40 mm².

19. The lamp of claim 18, wherein more than 2% of power in the SPD is emitted within a wavelength range from about 390 nm to about 430 nm.

20. The lamp of claim 18, wherein the lamp is characterized by a MR-16 form factor.

21. The lamp of claim 18, further comprising an optical lens, wherein a diameter of the optical lens is less than 40 mm.

22. The lamp of claim 18, wherein a partial shadow angular width is less than degree.

23. The lamp of claim 18, wherein a chromaticity variation Duv is less than 8, for two points in a partial shadow region.

24. The lamp of claim 18, wherein a chromaticity variation Duv of an emitted beam is less than 8 between a center of the emitted beam and a point with 10% intensity.

25. A light source comprising a plurality of light emitting diodes (LEDs), for which at least 2% of an SPD is in a range 390 nm to 430 nm, and such that a CIE Whiteness of a high-whiteness reference sample illuminated by the light source is within minus 20 points to plus 40 points of a CIE Whiteness of the same sample under illumination by a CIE reference illuminant of same CCT (respectively a blackbody radiator if CCT<5000K or a D illuminant if CCT>5000K).

26. A light source comprising LEDs, for which at least 2% of an SPD is in a range about 390 nm to about 430 nm, and such that a CIE Whiteness of a high-whiteness reference sample illuminated by the light source is within minus 20 points to plus 40 points of a CIE Whiteness of the same sample under illumination by a ceramic metal halide illuminant of same CCT.

27. A light source comprising a plurality of light emitting diodes (LEDs), wherein light emitted by the light source is characterized by a spectral power distribution in which at least 2% of the power is in a wavelength range from about 390 nm to about 430 nm, and a chromaticity in which a high-whiteness reference sample illuminated by the source is at least two Duv points and at most twelve Duv points away from a chromaticity of a white point of the light source, and the chromaticity shift is substantially toward the blue direction of the colorspace.

28. An optical device comprising:
a bulk gallium and nitrogen containing substrate having a surface region;
a n-type gallium and nitrogen containing epitaxial material formed overlying the surface region;
an active region comprising a double heterostructure well region, and at least one dummy well configured on each side of the double heterostructure well region, each of the at least one dummy wells having a width of about ten percent to about ninety percent of a width of the double heterostructure well region;
a p-type gallium and nitrogen containing epitaxial material formed overlying the active region; and
a contact region formed overlying the p-type gallium and nitrogen containing epitaxial material.
